(19) United States
(12) Patent Application Publication
(10) Pub. No.: US 2025/0380420 A1
(43) Pub. Date: Dec. 11, 2025

(54) MEMORY DEVICE INCLUDING CONCENTRIC CONDUCTIVE CONTACTS

(71) Applicant: Micron Technology, Inc., Boise, ID (US)

(72) Inventors: Matthew J. King, Boise, ID (US); Sidhartha Gupta, Boise, ID (US); Darwin A. Clampitt, Wilder, ID (US); Terry Hyunsik Kim, Boise, ID (US)

(21) Appl. No.: 19/232,238

(22) Filed: Jun. 9, 2025

Related U.S. Application Data
(60) Provisional application No. 63/658,281, filed on Jun. 10, 2024.

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

Some embodiments include apparatuses and methods of forming the apparatuses. One of the apparatuses includes: levels of dielectric materials interleaved with levels of conductive materials; a memory cell string including a pillar extending through the levels of conductive materials and the levels of dielectric materials, the levels of conductive materials including a first conductive level forming a first control gate associated with the memory cell string, and a second conductive level forming a second control gate associated with the memory cell string; a first conductive contact contacting the first conductive level; and a second conductive contact separated from the first conductive contact and contacting the second conductive level, at least a portion of the second conductive contact surrounding a portion of the first conductive contact.

### PRIORITY APPLICATION

This application claims the benefit of priority to U.S. Provisional Application Ser. No. 63/658,281, filed Jun. 10, 2024, which is incorporated herein by reference in its entirety.

### BACKGROUND

Dimensions of structures of some of the components in a memory device (e.g., a flash memory device) are relatively small (e.g., in nanometer size). At a certain dimension, structural damage (e.g., collapse) in part of the memory device may occur during fabrication. Such collapse can negatively affect yield, cost, performance, and reliability of the memory device. Further, a typical memory device has conductive contacts that are part of conductive paths to provide signals to components in a memory cell area of the memory cell. At a certain size, such conductive contacts can impact the device density of the memory device.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3A shows a detailed schematic diagram of two blocks of the memory device of FIG. 2, according to some embodiments described herein.

FIG. 3B shows an example of the memory device of FIG. 3A including multiple drain select gates, according to some embodiments described herein.

FIG. 4 shows a top view of a structure of a portion of the memory device of FIG. 3A including a region of a memory array, a conductive contact region, and structures between the blocks of the memory device, according to some embodiments described herein.

FIG. 5A shows a side view (e.g., cross-section) of a structure of a portion of the memory device of FIG. 4, including tiers of materials that include respective memory cells and control gates associated with the memory cells, according to some embodiments described herein.

FIG. 5B shows a variation of the memory device of FIG. 5A, including a memory cell pillar associated with multiple drain select gates, according to some embodiments described herein.

FIG. 6A shows a top view of the structure of the memory device of FIG. 4 and FIG. 5A, including conductive contacts and memory cell pillars, according to some embodiments described herein.

FIG. 6B shows a top view of the structure of the memory device of FIG. 6A, including conductive lines coupled to the conductive contacts, according to some embodiments described herein.

FIG. 7A shows a side view (e.g., cross-section) of a portion of the memory device of FIG. 6A, including conductive contacts associated with control gates of the memory device, according to some embodiments described herein.

FIG. 7B shows an enlarged portion of the memory device of FIG. 7A.

FIG. 7C shows a top view (e.g., cross-section) at location 7C of the memory device of FIG. 7A.

FIG. 7D shows a top view (e.g., cross-section) at location 7D of memory device 200 of FIG. 7A.

FIG. 7E shows a top view (e.g., cross-section) at line 7E of the memory device of FIG. 7A.

FIG. 7F shows an alternative dielectric liner of the memory device of FIG. 7A.

FIG. 7G shows alternative conductive contacts associate with select lines (e.g., drain and source select lines) of the memory device of FIG. 7A.

FIG. 8A and FIG. 8B show a memory device that can be a variation of the memory device of FIG. 7A, according to some embodiments described herein.

FIG. 9 shows a memory device that can be a variation of the memory device of FIG. 6A and FIG. 7A, according to some embodiments described herein.

FIG. 10 through FIG. 25 show different views of elements during processes of forming a memory device including forming conductive contacts of the memory device, according to some embodiments described herein.

FIG. 26 through FIG. 29 show different views of a structure of another memory device, according to some embodiments described herein.

FIG. 30A through FIG. 52B show different views of elements during processes of forming a memory device including forming conductive contacts of the memory device, according to some embodiments described herein.

### DETAILED DESCRIPTION

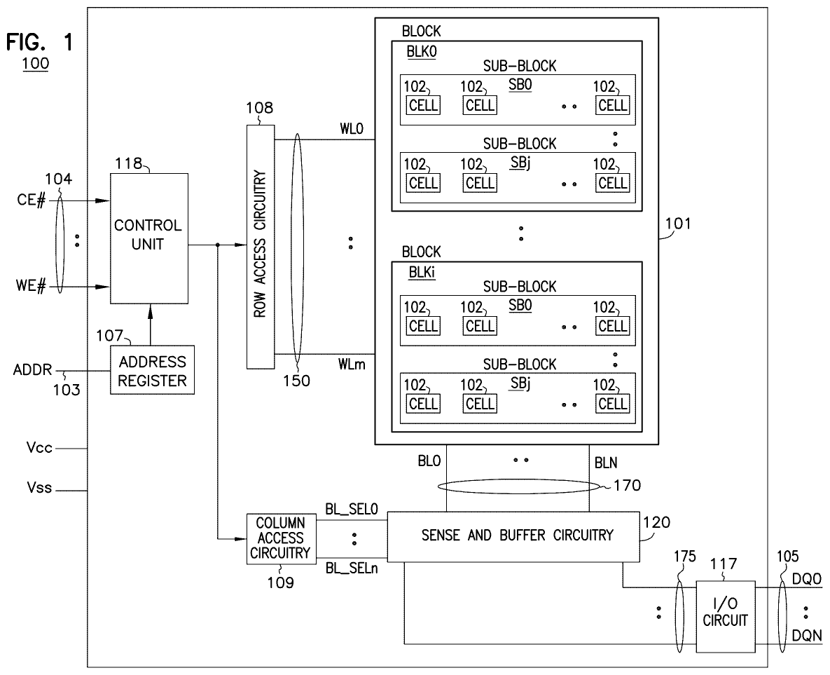

The techniques described herein involve a memory device including memory cells formed in tiers (different physical levels) of the memory device. The tiers include respective levels of conductive materials. The conductive materials form part of control gates (e.g., word lines) associated with the memory cells. The described memory device includes conductive contacts associated with the control gates. In an example, multiple conductive contacts can be formed in a contact opening (e.g., hole). The multiple conductive contacts are associated with different control gates. The conductive contacts formed using the described techniques can increase device density (e.g., memory cell density) of the memory device. Moreover, the described conductive contacts can mitigate or prevent damage (e.g., tier collapse, tier deformity, or both) to part of the tiers of the memory device during fabrication. As described in more detail below, the techniques described herein can improve at least one of device area, yield, cost, performance, and reliability associated with the memory device. Other improvements and benefits of the techniques described herein are further discussed below with reference to FIG. 1 through FIG. 52B.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

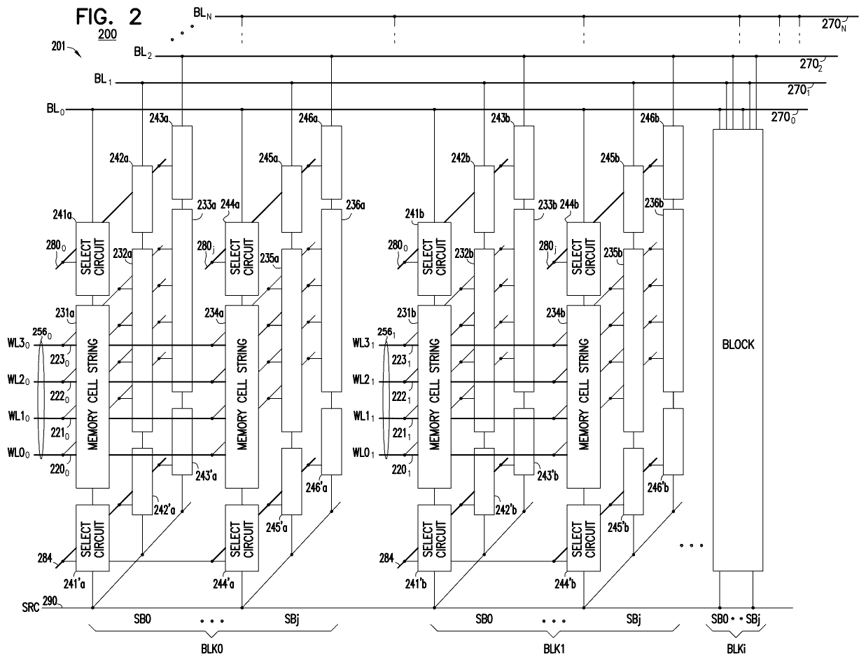

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 24.

FIG. 2 shows a general schematic diagram of a portion of a memory device 200 including a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

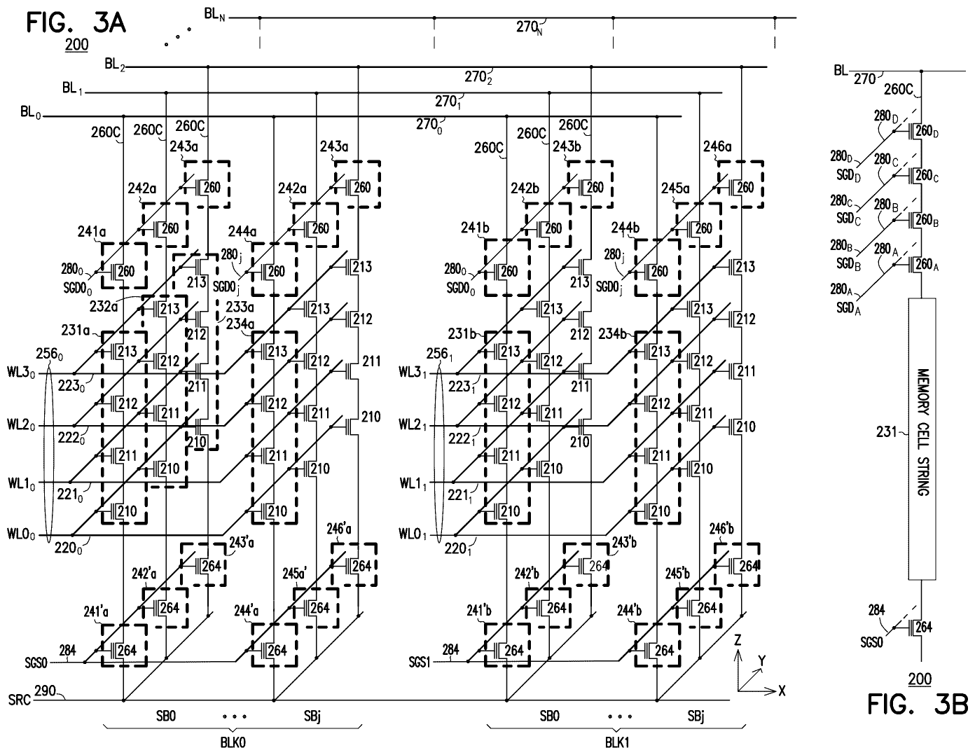

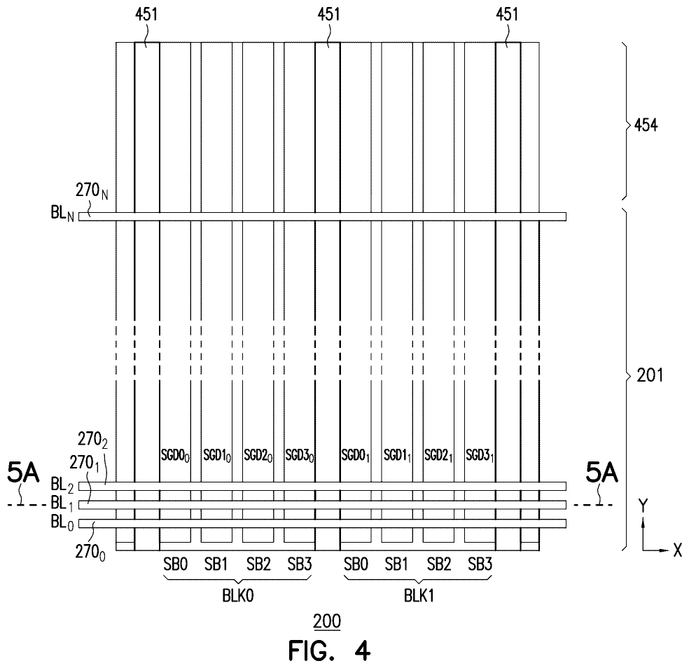

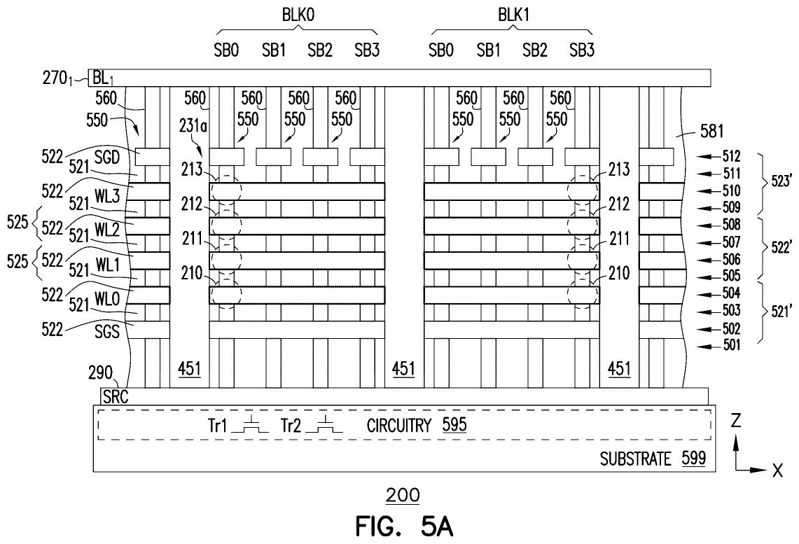

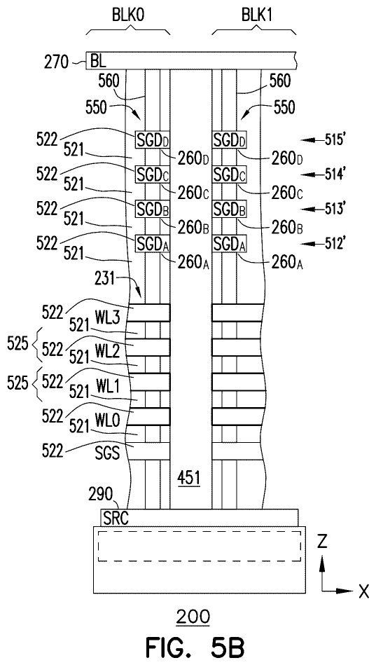

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3A and FIG. 4) and a pillar (e.g., pillar 550 in FIG. 5A) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3A) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3A) coupled between source 290 and a respective memory cell string. The source select gate (e.g., transistor) can be controlled (e.g., turned on or turned off) by a signal on a respective source select line based on a voltage provided to the signal.

FIG. 3A shows a detailed schematic diagram including blocks of the blocks BLK0 and BLK1 of memory device 200 of FIG. 2, according to some embodiments described herein. In FIG. 3A, directions X, Y, and Z in FIG. 3A can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5A). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3A. As shown in FIG. 3A, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3A, similar drain select lines (and their associated signals) are given the same labels for simplicity. However, as shown in FIG. 3A, the drain select lines (from the same block or from different blocks) of memory device 200 are electrically separated from each other and carry different signals (although the signals are given the same labels).

As shown in FIG. 3A, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3A, each of the memory cell strings (e.g., memory cell string 231a) of memory device 200 can include series-connected memory cells that include one of memory cells 210, one of memory cells 211, one of memory cells 212, and one of memory cells 213. FIG. 3A shows an example of four memory cells 210, 211, 212, and 213 in each memory cell string. The number of memory cells in each memory cell string can vary. For example, each memory string can include up to hundreds (or more) of memory cells.

As shown in FIG. 3A, memory device 200 can include conductive connections 260C coupled between respective select gates 260 and respective data lines memory cells to respective data lines 270₀ through 270_{N}. In the physical structure of memory device 200, each conductive connection 260C is part of a contact structure (e.g., contact structure 560 in FIG. 5A) associated with a memory cell pillar (e.g., pillar 550 in FIG. 5A) of memory device 200.

As shown in FIG. 3A, each drain select circuit (e.g., select circuit 241a) can include one of select gates 260. Each source select circuit (e.g., select circuit 241′a) can include one of select gates 264.

Each select gate 260 in FIG. 3A can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor (e.g., FET)) between the portion of the conductive material and the portion of the channel material.

FIG. 3A shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 3B shows an example of memory device 200 including four select gates (e.g., four drain select gates) 260_{A}, 260_{B}, 260_{C}, and 260_{D} associated with four select lines 280_{A}, 280_{B}, 280_{C}, and 280_{D}. Memory device 200 can use signals SGD_{A}, SGD_{B}, SGD_{C}, and SGD_{D} on select lines 280_{A}, 280_{B}, 280_{C}, and 280_{D}, respectively, to control (turn on or turn off) select gates 260_{A}, 260_{B}, 260_{C}, and 260_{D}, respectively. Data line 270 and associated signal BL can be one of data lines 270₀ through 270_{N} associated with one of signals BL₀ through BL_{N}, respectively. Memory cell string 231 and associated conductive connection 260C can be one of the memory cell strings (e.g., memory cell string 231a) associated with conductive connection 260C of memory device 200 of FIG. 3A.

FIG. 3B shows one source select gate (e.g., select gate 264) and one source select signal (e.g., signal SGS0) on a source select line (e.g., select line 284). However, memory device 200 can include two or more source select gates (in the Z-direction) like select gates 260_{A}, 260_{B}, 260_{C}, and 260_{D}.

FIG. 4 shows a top view of a structure of a portion of memory device 200 of FIG. 2 and FIG. 3A including a region of memory array 201 including blocks BLK0 and BLK1, a region 454, and structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3A are also not repeated.

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1). Structures 451 can be called a dielectric structure or a slit structures. The regions of memory device 200 at which structures 451 are located can be called slit regions.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have a structure like block BLK0. As shown in FIG. 4, block BLK1 can include sub-blocks SB0, SB1, SB2, and SB3, select lines (e.g., drain select lines) SGD0₁, SGD1₁, SGD2₁, and SGD3₁.

A side view side view (e.g., cross-section) at memory array (memory cell array) 201 of memory device 200 along line 5A-5A in FIG. 4 is shown in FIG. 5A.

FIG. 5A shows a side view (e.g., cross-section) of a structure of a portion of memory device 200 of FIG. 4 including tiers (tiers of materials) 525 that include respective memory cells and control gates associated with (e.g., to control) the memory cells, according to some embodiments described herein. FIG. 5A also partially shows other blocks (on the left and right sides of blocks BLK0 and BLK1) of memory device 200.

As shown in FIG. 5A, memory device 200 can include a substrate 599, source 290 formed over substrate 599, and different levels 501 through 512 over substrate 599 in the Z-direction. Levels 501 through 512 are physical device levels of memory device 200 over substrate 599. Memory device 200 can include decks 521′, 522′, and 523′. Each of decks 521′, 522′, and 523′ can include part of memory devices 200 in different physical levels (e.g., levels 501 through 512) of memory device 200.

Memory device 200 can include a dielectric material 581 formed over at least a portion of memory device 200. Memory cells 210, 211, 212, and 213 of the memory cell strings (e.g., memory cell string 231a in FIG. 3A) of respective sub-blocks SB0, SB1, SB2, and SB3 of each of blocks BLK0 and BLK1 can be formed over substrate 599 and source 290 (e.g., formed vertically in Z-direction in respective levels among levels 501 through 512).

As shown in FIG. 5A, data line 270₁ (associated with signal BL1) can extend in the X-direction across the blocks (e.g., blocks BLK0 and BLK1 and other blocks) of memory device 200. Data line 270₁ can be shared by respective memory cell strings (including memory cell string 231a) of the blocks.

In FIG. 5A, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5A, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3A. In another example, in block BLK1, the select line indicated by signal SGS can correspond to the select line (e.g., source select line) associated with signals SGS1 of block BLK1 shown in FIG. 3A.

In FIG. 5A, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 3A. In another example, in block BLK1 in FIG. 5A, the control gates indicated by signals WL0, WL1, WL2, and WL3 can correspond to respective control gates associated with signals WL0₁, WL1₁, WL2₁, and WL3₁, respectively, of block BLK1 shown in FIG. 3A.

As shown in FIG. 5A, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form respective control gates (associated with signals WL0, WL1, WL2, and WL3) in the respective block. As shown in FIG. 5A, dielectric materials 521 can be located on respective levels among levels 501 through 512. Conductive materials 522 can be located on respective levels (e.g., levels 502, 504, 506, 508, 510, and 512) among levels 501 through 512 that are interleaved with the levels of dielectric materials 521. Examples of conductive materials 522 (which form the control gates) include a single conductive material (e.g., single metal, e.g., tungsten) or a combination of different layers of conductive materials. For example, each of the control gates of blocks BLK0 and BLK1 can include (e.g., have multi-layers of) aluminum oxide, titanium nitride, tungsten.

As shown in FIG. 5A, dielectric materials 521 can form levels of dielectric materials 521. Conductive materials 522 can form levels of conductive materials 522 that are interleaved with the levels of dielectric materials 521. The levels of dielectric materials 521 and the levels of conductive materials 522 can form tiers 525 of memory device 200. Each tier 525 can include a level of dielectric material 521 and a level of conductive material 522. For simplicity, only some of tiers 525 are labeled in FIG. 5A. As shown in FIG. 5A, tiers 525 can be located one over another and can include respective levels of memory cells 210, 211, 212, and 213, and control gates associated with the memory cells. FIG. 5A shows a few tiers (e.g., only two tiers 525 are labeled) of memory device 200 as an example. However, memory device 200 can include up to hundreds of tiers (or more than hundreds of tiers).

As shown in FIG. 5A, memory device 200 can include pillars (memory cell pillars) 550 in blocks BLK0 and BLK1. Each of pillars 550 can be part of a respective memory cell string (e.g., memory cell string 231a). Each of the pillars 550 can have length extending through at least a portion of each of decks 521′, 522′, and 523′ in the Z-direction (e.g., extending vertically from substrate 599) between substrate 599 and data line 270. As shown in FIG. 5A, the Z-direction is also a direction at which the length of pillar 550 extends from one tier to another tier, which is also a direction from levels of dielectric materials 521 to levels of conductive materials 522.

As shown in FIG. 5A, memory device 200 can include contact structures (e.g., data line contact structures) 560. Each pillar 550 can be coupled to a data line by a respective contact structure 560. Each contact structure 560 can be considered as part of a respective pillar 550 and can include a conductive material (or conductive materials) to allow electrical signal between pillar 550 and a respective data line.

As shown in FIG. 5A, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5A, memory device 200 can include circuitry 595 located in (e.g., formed in) substrate 599. At least a portion of the circuitry 595 can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5A, source 290 can include a conductive material (or materials, e.g., different levels of different materials) and can have a length extending in the X-direction. FIG. 5A shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

FIG. 5B shows an example structure of memory device 200 of FIG. 5A including four select gates (e.g., four drain select gates) 260_{A}, 260_{B}, 260_{C}, and 260_{D} associated with a memory cell string (e.g., memory cell string 231). The other elements of memory device 200 of FIG. 5B can be the same as those of memory device 200 shown in FIG. 5A. Memory device 200 of FIG. 5B can represent the structure of memory device 200 that is schematically shown in FIG. 3B. FIG. 5B shows an example of memory device 200 including a multiple of four select gates (e.g., four drain select gates) associated with signals SGD_{A}, SGD_{B}, SGD_{C}, and SGD_{D}. Conductive materials 522 on respective levels 512′, 513′, 514′, and 515′ form the select lines (e.g., four select lines) associated with the select gates. Like memory device 200 of FIG. 5A, memory device 200 of FIG. 5B can include contact structures (e.g., data line contact structures) 560 associated with pillars (memory cell pillars) 550.

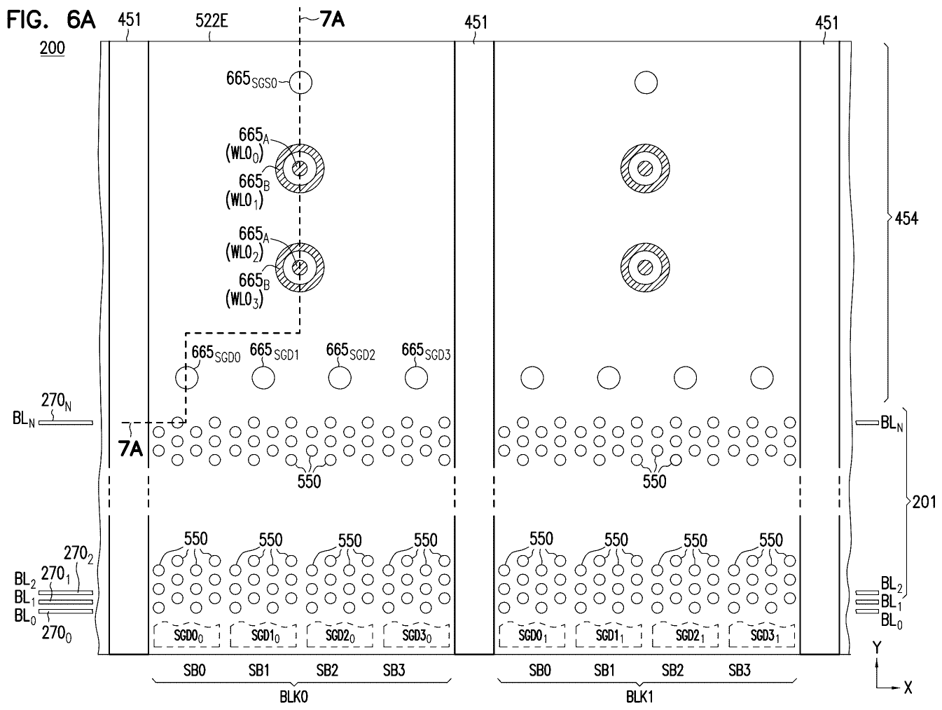

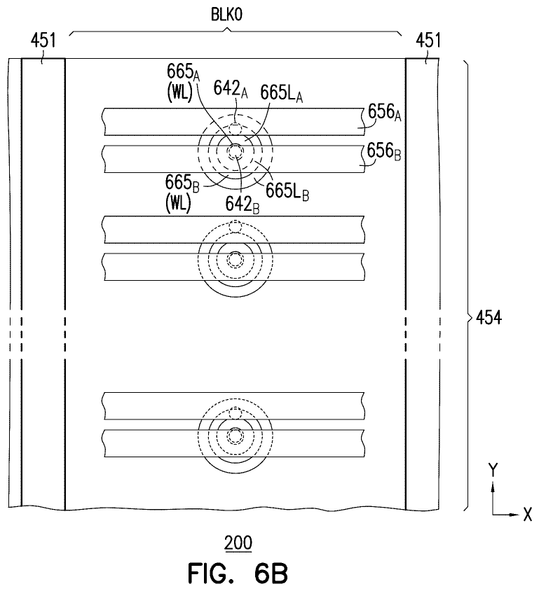

FIG. 6A shows a top view of a structure of memory device 200 of FIG. 4, according to some embodiments described herein. FIG. 6B shows a top view of additional elements of memory device 200 of FIG. 6A, according to some embodiments described herein. FIG. 6A shows top views of pillars 550 located in the region included in memory array 201, which is adjacent region 454. Region 454 can be called a conductive contact region (e.g., word line conductive contact region) of memory device 200.

As shown in FIG. 6A, in region 454, memory device 200 can include conductive contacts (e.g., word line contacts) 665_{A} and 665_{B}, conductive contacts (e.g., drain select line contacts) 665_{SGDO}, 665_{SGD1}, 665_{SGD2}, and 665_{SGD3}), and conductive contact (e.g., source select line contact) 665_{SGD0}. Conductive contacts 665_{A} and 665_{B} can include metal (e.g., tungsten or other conductive materials).

For simplicity, FIG. 6A uses the same label (e.g., 665_{A}) for two different conductive contacts. FIG. 6A shows four conductive contacts in which two different conductive contacts are labeled with 665_{A} and two other conductive contacts are labeled with 665_{B}.

Conductive contacts 665_{A} and 665_{B} that are adjacent each other can be called a pair of conductive contacts 665_{A} and 665_{B}. FIG. 6A shows four conductive contacts (two pair of conductive contacts) 665_{A} and 665_{B} as an example. However, memory device 200 can include up to hundreds of conductive contacts (or more than hundreds of four conductive contacts). In an example, the number of conductive contacts (like conductive contacts 665_{A} and 665_{B}) can be equal to the number of the control gates of memory device 200.

Although not shown in FIG. 6A for simplicity, memory device 200 (as shown in FIG. 6B) can include elements associated with conductive contacts 665_{A} and 665_{B}, including dielectric liners 665L_{A} and 665L_{B}, conductive connections 642_{A} and 642_{B}, and conductive lines 656_{A} and 656_{B}.

In FIG. 6A, each of conductive contacts 665_{A} and 665_{B} can contact (form an electrical connection with) a respective control gate (located under conductive contacts 665_{A} and 665_{B}, hidden from the top view of FIG. 6A). Thus, conductive contacts (a pair of conductive contacts) 665_{A} and 665_{B} can contact two respective control gates. In the example of FIG. 6A, four conductive contacts 665_{A} and 665_{B} can contact four control gates (e.g., control gates associated with signals WL0₀, WL1₀, WL2₀, and WL3₀).

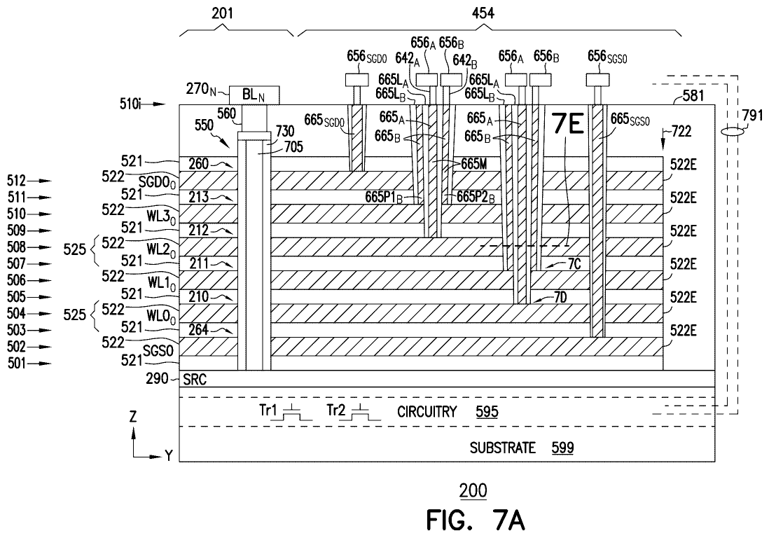

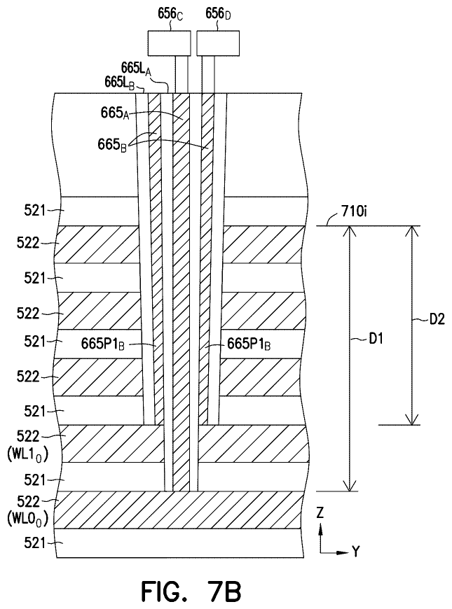

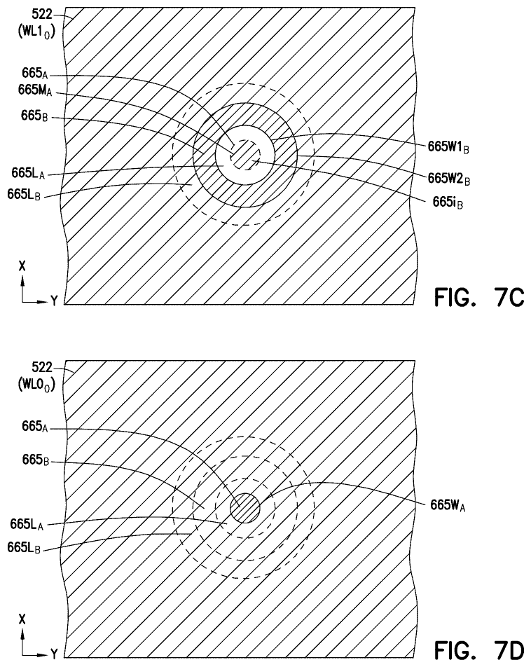

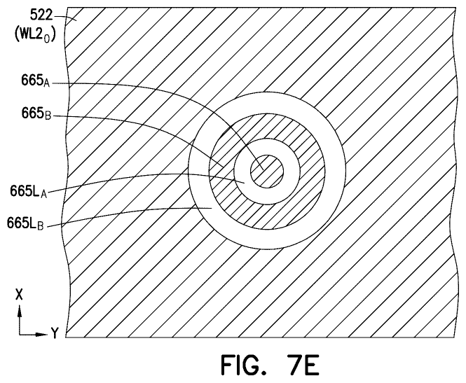

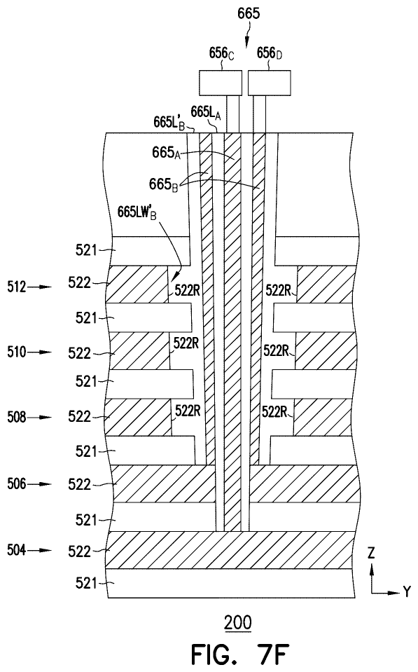

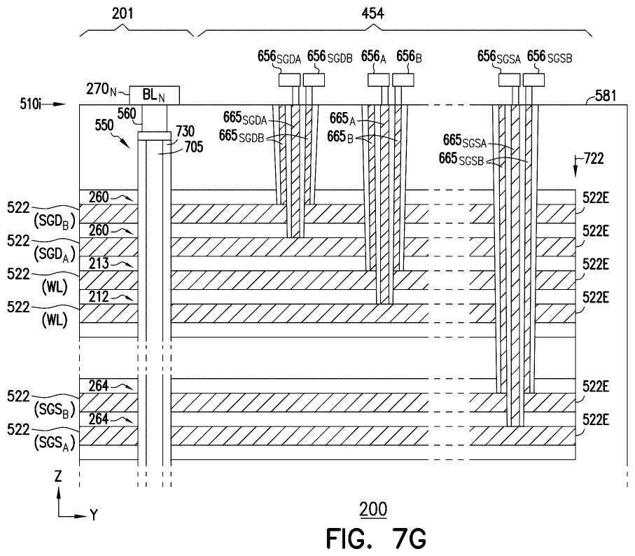

Conductive contacts 665_{A} and 665_{B} can be part of respective access lines (e.g., word lines) of memory device 200. Conductive contacts 665_{A} and 665_{B} allow signals (e.g., signals WL0₀, WL1₀, WL2₀, and WL3₀ in block BLK0 in FIG. 3A) to be provided to respective control gates of block BLK0 through conductive contacts 665_{A} and 665_{B}. FIG. 7B (described in more detail below) shows side views (e.g., cross-sections) of conductive contacts 665_{A} and 665_{B}. In FIG. 6A (and in FIG. 7A), each control gate (associated with one of signals WL0₀, WL1₀, WL2₀, and WL3₀) in block BLK0 has an edge 522E. FIG. 6A shows one edge 522E to indicate that edges 522E (shown in FIG. 7A) may be aligned (e.g., vertically aligned) with each other in the Z-direction and are hidden from the top view of memory device 200 in FIG. 6A.

In FIG. 6A, select lines associated with signals SGD0₀, SGD1₀, SGD2₀, and SGD3₀ in block BLK0 and signals SGD0₁, SGD1₁, SGD2₁, and SGD3₁ in block BLK1 are partially shown as dotted lines. Each of sub-blocks SB0, SB1, SB2, and SB3 can include multiple rows of pillars 550 associated with a respective select line (one of the select lines associated with signals SGD0₀, SGD1₀, SGD2₀, and SGD3₀). As shown in FIG. 6A, the multiple rows of pillars 550 can be located one after another in the X-direction (rows having lengths parallel to the Y-direction). FIG. 6A shows an example where each sub-block includes four rows of pillars 550 (side-by-side in the X-direction). However, the number of rows in the sub-blocks can be less than four or greater than four.

In FIG. 6A, data lines 270₀ through 270_{N} are partially shown for simplicity. Data lines 270₀ through 270_{N} can extend across (in the X-direction) the blocks (e.g., blocks BL0 and BL1). Data lines 270₀ through 270_{N} can be located over and in electrical contact with pillars 550. Contact structures 560 (shown in FIG. 5A or FIG. 5B) coupled between pillars 550 and data lines 270₀ through 270_{N} are not shown in FIG. 6A. Each pillar 550 in the same sub-block of a block can be coupled to a separate (e.g., unique) data line among data lines 270₀ through 270_{N}.

As shown in FIG. 6A, block BLK1 includes conductive contacts (e.g., not labeled) and other elements similar to those of block BLK0. For simplicity, the descriptions of the elements of block BLK1 are omitted herein.

A side view (e.g., cross-section) along line 7A-7A in FIG. 6A of block BLK0 is shown in FIG. 7A.

FIG. 6B shows a top view of a portion of memory device 200 including elements associated with conductive contacts 665_{A} and 665_{B} of block BLK0. For simplicity, some of the elements of memory device 200 of FIG. 6A are omitted from FIG. 6B. As shown in FIG. 6B, memory device 200 can include dielectric liners 665L_{A} and 665L_{B}, conductive connections 642_{A} and 642_{B}, and conductive lines 656_{A} and 656_{B}. Only two of the conductive lines 656_{A} and 656_{B} are labeled. Conductive lines 656_{A} and 656_{B} (which are partially shown in FIG. 6B) can have respective lengths in the X-direction. Each of conductive contacts 665_{A} and 665_{B} is associated with (can be coupled to) a separate conductive line. Thus, a pair of conductive contacts 665_{A} and 665_{B} are associated with a pair of conductive lines 656_{A} and 656_{B}, as shown in FIG. 6B. Conductive connection 642_{A} (under conductive lines 656_{A} from top view of FIG. 6B) can be formed to connect (electrically couple) a respective conductive contact 665_{A} to a respective conductive line 656_{A}. Conductive connection 642_{B} (under conductive lines 656_{B} from top view of FIG. 6B) can be formed to connect (electrically couple) a respective conductive contact 665_{B} to a respective conductive line 656_{B}. Thus, as shown in FIG. 6B, two conductive connections 642_{A} and 642_{B} can connect two respective conductive lines 656_{A} and 656_{B} to two respective conductive contacts 665_{A} and 665_{B}. Conductive lines 656_{A} and 656_{B} can be part of conductive paths (e.g., conductive paths 791 in FIG. 7A) coupled to components (e.g., word line drivers) of circuitry 595 (FIG. 7A) of memory device 200. Conductive lines 656_{A} and 656_{B} of a block (e.g., block BLK0) can be formed (e.g., patterned) such that they can be electrically separated from other conductive lines 656_{A} and 656_{B} (not shown) of another block (e.g., block BLK1). Dielectric liners 665L_{A} and 665L_{B} can separate (electrically isolate) conductive contacts 665_{A} and 665_{B} from each other and from adjacent elements of memory device 200. Dielectric liners 665L_{A} and 665L_{B} can be called dielectric spacers.

FIG. 7A shows a side view of a portion of memory device 200 including conductive contacts 665_{A} and 665_{B}, 665_{SGD0}, and 665_{SGS0} in region 454, and pillar (memory cell pillar) 550 in memory array 201, according to some embodiments described herein. Levels 501 through 512 and tiers 525 of memory device 200 in FIG. 7A are the same as those shown in FIG. 5A. As shown in FIG. 7A, pillar 550 can be located in the portion of memory device 200 that includes memory array 201, which is also shown in top view in FIG. 4 and FIG. 6A. Pillar 550 can extend through conductive materials 522 (which form the control gates and the select lines) and dielectric materials 521 in the portions that include memory array 201.

As shown in FIG. 7A, memory device 200 can include a structure 730 and a dielectric material 705 that can be part of pillar 550. Structure 730 and a dielectric material 705 can extend continuously (in the Z-direction) along the length of the respective pillar 550. Dielectric material 705 can include silicon dioxide. Structure 730 can be electrically coupled to source 290 and a respective data line (e.g., one of data lines 270₀ through 270_{N} in FIG. 3A and FIG. 6A). Structure 730 of a respective pillar 550 in a block is adjacent portions of respective control gates of that block. For example, structure 730 of pillar 550 in block BLK0 is adjacent the control gates associated with signals WL0₀, WL1₀, WL2₀, and WL3₀, respectively.

Structure 730 can include a conductive structure that can be part of a conductive path (e.g., pillar channel structure) to conduct current between a respective data line (e.g., one of data line 270₀ through 270_{N} in FIG. 3A and FIG. 6A) coupled to structure 730 and source 290. Structure 730 can also include a material (or materials) that can form a charge storage element (e.g., a memory element) of a respective memory cell (among memory cells 210, 211, 212, and 213) located along a portion of pillar 550. As an example, structure 730 can be part of an ONOS (SiO₂, Si₃N₄, SiO₂, Si) where Si₃N₄ material can form a charge storage element of a respective memory cell, and Si material can be part of the pillar channel structure of pillar 550. In another example, structure 730 include can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure) where the floating gate structure can form a charge storage element of a respective memory (among memory cells 210, 211, 212, and 213) located along a portion of pillar 550.

As shown in FIG. 7A, the control gates associated with signals WL0₀, WL1₀, WL2₀, and WL3₀, and the select lines associated with signals (e.g., drain select signal and source select signal) SGD0₀ and SGS0 can be structured (e.g., patterned), such that they may have the same length in the Y-direction. For example, the control gates (formed from respective conductive materials 522) associated with signals WL1₀, WL2₀, and WL3₀ can have the same length (in the Y-direction) measuring between pillar 550 and edges 522E of respective the control gates. Edges 522E are part of respective conductive materials 522. As shown in FIG. 7A, the control gates associated with signals WL0₀, WL1₀, WL2₀, and WL3₀ can have the same length, such that edges 522E may be aligned (e.g., vertically aligned) with each other at a reference location (e.g., reference point), such as reference location 722.

Thus, as shown in FIG. 7A, the conductive contacts (e.g., conductive contact 665_{A} and 665_{B}, 665_{SGD0}, and 665_{SGS0}) can be between pillar 550 and edges 522E. For example, the conductive contact 665_{B} associated with the control gate associated with respective signal WL1₀ on level 506 is between pillar 550 and edge 522E of conductive material 522 on level 506 and also between pillar 550 and edge 522E of conductive material 522 on level 504 (associated with signal WL0₀).

In another example, the conductive contact 665_{A} associated with the control gate associated with signal WL0₀ on level 504 is between pillar 550 and edge 522E of conductive material 522 on level 504 and also between pillar 550 and edge 522E of conductive material 522 on level 506 (associated with signal WL1₀).

As shown in FIG. 7A, conductive contacts (e.g., word line contacts) 665_{A} and 665_{B}, conductive contact (e.g., drain select line contact) 665_{SGD0}, and conductive contact (e.g., source select line contact) 665_{SGS0} can include a respective length extending in the Z-direction. The lengths of conductive contact 665_{A} and 665_{B} are different from each other (unequal to each other). The length of a particular conductive contact (conductive contact 665_{A} or 665_{B}) can be a distance (the measurement) in the Z-direction from the control gate associated with that particular conductive contact to a reference location (e.g., at level 510i) in memory device 200. For purposes of measuring the lengths of different conductive contacts (e.g., conductive contacts 665_{A} and 665_{B}) in this description, the same reference location (e.g., at level 510i) with respect to the Z-direction is used for the length measurement. FIG. 7A shows a particular reference location (e.g., at level 510i) in memory device 200 as an example. However, the reference location can be at another location in memory device 200 as long as the same reference point is used for purposes of measuring the lengths of different conductive contacts.

For example, as shown in FIG. 7A, level 510 is the conductive material 522 that forms the control gate associated with signal WL3₀. Thus, the length of the conductive contact 665_{B} coupled to the control gate associated with signal WL3₀ can be the distance (the measurement) in the Z-direction from level 510i to level 510. In another example, as shown in FIG. 7A, level 508 is the level of the conductive material 522 that forms the control gate associated with signal WL2₀. Thus, the length of the conductive contact 665_{A} coupled to the control gate associated with signal WL2₀ can be the distance (the measurement) in the Z-direction from level 510i to level 508.

As shown in FIG. 7A, each conductive contact 665_{A} and 665_{B} can include conductive material 665M extending in a direction from one level of conductive material 522 to another level of conductive material 522. Dielectric liner 665L_{A} can separate (electrically isolate) conductive contact 665_{A} and 665_{B} from each other. Dielectric liner 665L_{B} can separate (electrically isolate) conductive contact 665_{B} from conductive materials 522 except for one of the conductive materials 522 that forms the control gate associated with conductive contact 665_{B}.

As shown in FIG. 7A, conductive contact 665_{B} can include a portion 665P1_{B} and a portion 665P2_{B} opposite portion 665P1_{B} in the X-direction. Portion 665P1_{B} can be located on a side (e.g., left side in the X-direction) of conductive contact 665_{A}, Portion 665P2_{B} can be located on another side (e.g., right side in the X-direction) of conductive contact 665_{A}.

As shown in FIG. 7A, memory device 200 can include conductive paths (e.g., conductive routings) 791 to form circuit paths between circuitry 595 and other elements of memory device 200. For example, conductive lines 656_{A} and 656_{B} (FIG. 6B) associated with the control gates (e.g., control gates associated with signals WL0₀, WL1₀, WL2₀, and WL3₀ in FIG. 7A) of memory device 200 can be part of (or can be coupled to) conductive paths 791. This allows the control gates to couple to circuitry 595 through conductive lines 656_{A} and 656_{B} (FIG. 6B) and conductive paths 791 (FIG. 7A).

FIG. 7B shows an enlarged portion of memory device 200 of FIG. 7A including respective lengths of conductive contacts 665_{A} and 665_{B}. FIG. 7C shows a top view (e.g., cross-section) at location 7C of memory device 200 of FIG. 7A. FIG. 7D shows a top view (e.g., cross-section) at location 7D of memory device 200 of FIG. 7. FIG. 7E shows a top view (e.g., cross-section) at line 7E of memory device 200 of FIG. 7A. FIG. 7F shows an alternative dielectric liner 665L′_{B} of memory device 200 of FIG. 7A. FIG. 7G shows alternative conductive contacts associate with select lines (e.g., drain and source select lines) of memory device 200 of FIG. 7A.

FIG. 7B shows an example reference point 710i and two distances D1 and D2 of an example measurement associated with conductive contacts 665_{A} and 665_{B}. Reference point 710i is at the level corresponding to the level of conductive material 522 that is separated (electrically isolated from) conductive contacts 665_{A} and 665_{B}. As shown in FIG. 7B, distance D1 is the distance between reference point 710i and the level at which conductive material 522 associated with signals WL0₁ contacts conductive contact and 665_{A}. Distance D2 is the distance between reference point 710i and the level at which conductive material 522 associated with signals WL0₀ contacts conductive contact and 665_{B}. As shown in FIG. 7B, conductive contacts 665_{A} and 665_{B} have different lengths, such that distance D1 is greater than distance D2.

As shown in FIG. 7C (e.g., from a top view), the cross-section of conductive contact 665_{B} can have a ring shape (e.g., a donut shape). Conductive contact 665_{B} can have a side wall (e.g., inner side wall) 665W1_{B} and a side wall (e.g., outer side wall) 665W2_{B} surrounding side wall 665W1_{B}. Conductive material 522 in FIG. 7C corresponds to conductive material 522 on level 506 (FIG. 7A) that forms the control gate associated with signal WL1₀. Thus, as shown in FIG. 7C, conductive contact 665_{B} contacts (is electrically coupled to) the control gate associated with signal WL1₀. As shown in FIG. 7C, conductive contact 665_{B} surrounds a region 665i_{B} (an internal region of the ring shape). Region 665i_{B} is surrounded by dielectric liner 665L_{A}. As shown in FIG. 7C, material 665M_{A} of conductive contact 665_{A} can fill region 665i_{B}. Dielectric liner 665L_{A} is adjacent side wall 665W1_{B} of conductive contact 665_{B} and surrounds conductive contact 665_{A}. Conductive contact 665_{B} can surround dielectric liner 665L_{A}. Thus, as shown in FIG. 7C, conductive contact 665_{B} can also surround conductive contact 665_{A}.

FIG. 7D shows top views (e.g., cross-section) at location 7D of FIG. 7A, according to some embodiments described herein. As shown in FIG. 7D (e.g., from a top view), conductive contact 665_{A} can have a solid cross-section that has circular (or oval) shape. Conductive contact 665_{A} can have a side wall 665W_{A}. Conductive material 522 surrounds (encircles) and contacts side wall 665W_{A} of conductive contact 665_{A}. Conductive material 522 in FIG. 7D corresponds to conductive material 522 on level 504 (FIG. 7A) that forms the control gate associated with signal WL0₀. Thus, as shown in FIG. 7D, conductive contact 665_{A} contacts (is electrically coupled to) the control gate associated with signal WL0₀.

FIG. 7E shows top views (e.g., cross-section) along lines 7E of FIG. 7A, according to some embodiments described herein. As shown in FIG. 7E, dielectric liner 665L_{A} is between conductive contact 665_{A} and conductive contact 665_{B} and surrounding conductive contact 665_{A}. As shown in FIG. 7A, dielectric liner 665L_{B} is between conductive contact 665_{B} and the levels of dielectric materials 521 and the level of conductive materials 522. As shown in FIG. 7E, dielectric liner 665L_{B} is surrounded by a conductive materials 522. Although not shown in FIG. 7E, dielectric liner 665L_{B} is also surrounded by dielectric materials 521.

FIG. 7F shows memory device 200 including an alternative dielectric liner 665L′_{B}. Dielectric liner 665L′_{B} can have a different structure (e.g., different shape of the side walls) relative to the structure of dielectric liner 665L_{B} (FIG. 7A and FIG. 7B). As shown in FIG. 7F, dielectric liner 665L′_{B} can have a side wall 665LW′_{B} that include recesses 522R. Forming dielectric liner 665L′_{B} can further increase the effective width of dielectric isolation (thereby improving electrical isolation) between conductive contacts 665_{B} adjacent conductive materials 522 (e.g., on levels 506, 508, 510, and 512) that are not coupled to a contact (e.g., formed in opening 665 and adjacent control gates that are not coupled conductive contacts 665_{B}).

FIG. 7G shows an alternative structure of memory device 200 including multiple select lines (e.g., drain select lines) associated with signals SGD_{A} and SGD_{B}, and multiple select lines (e.g., source select lines) associated with signals SGS_{A} and SGS_{B}. As shown in FIG. 7G, respective conductive materials 522 can form the select lines associated with signals SGD_{A} and SGD_{B}, the select lines associated with signals SGS_{A} and SGS_{SB}, and the control gates associated with signal WL (which is similar to signals WL0₀, WL1₀, WL2₀, and WL3₀ of FIG. 7A). As shown in FIG. 7G, memory device 200 can include conductive contacts 665_{SGDA} and 665_{SGDB} coupled to the select lines associated with signals SGD_{A} and SGD_{B}, respectively, and conductive contacts 665_{SGSA} and 665_{SGSB} coupled to the select lines associated with signals SGS_{A} and SGS_{B}, respectively. Conductive contacts 665_{SGDA} and 665_{SGDB} can have structures similar to conductive contacts 665_{A} and 665_{B}, respectively. Conductive contacts 665_{SGSA} and 665_{SGSB} can have structures similar to conductive contacts 665_{A} and 665_{B}, respectively.

Memory device 200 including conductive contacts as described above (e.g., conductive contacts 665_{A} and 665_{B}) allows the memory device 200 to have a relatively small region (e.g., small area) for conductive contacts associated with control gates of the memory device 200. This can leave more room for the memory cell area, thereby increasing memory density. This can also lead to improvement in cost. Further, including conductive contacts like conductive contacts 665_{A} and 665_{B} in memory device 200 can mitigate or prevent damage (e.g., tier collapse, tier bending, or both) in part of the memory device 200 (e.g., at the locations of conductive contacts 665_{A} and 665_{B}) during processing. This can improve yield and cost. Moreover, the absence of tier collapse and tier bending allow the memory device 200 to maintain proper electrical connections between circuit elements (e.g., be less susceptible to electrical short between circuit elements) of memory device 200. This can lead to improvement in at least one of performance and reliability of memory device 200.

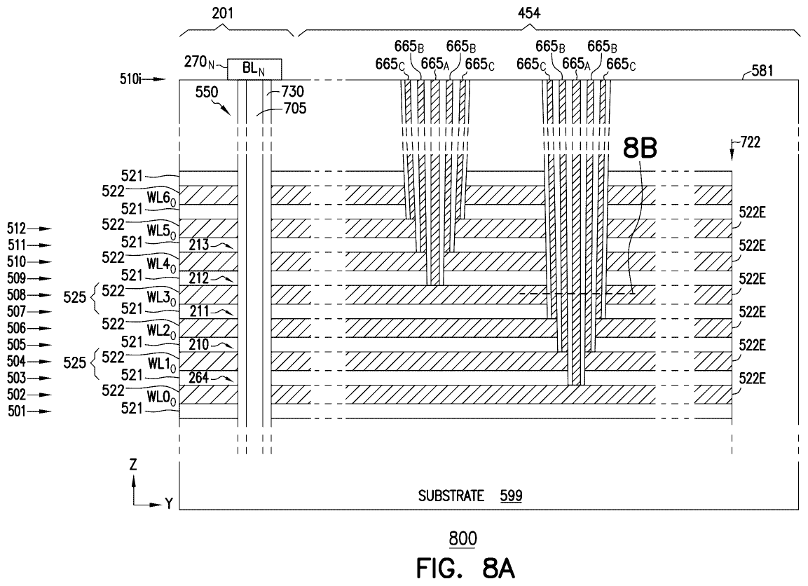

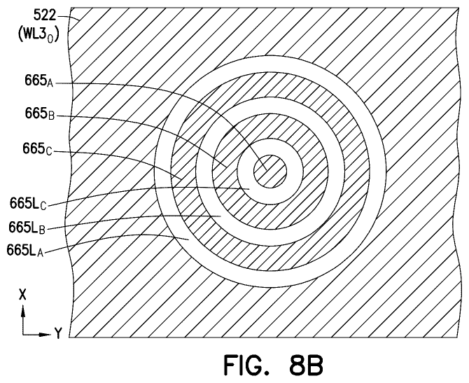

FIG. 8A and FIG. 8B show a memory device 800 that can be variations of memory device 200, according to some embodiments described herein. FIG. 8B shows a top view of FIG. 8A at line 8B. As shown in FIG. 8A and FIG. 8B, memory device 800 can include elements that are similar to or the same as the elements of memory device 200 of FIG. 7A. For simplicity, descriptions of similar or the same elements between memory devices 200 and 800 are not repeated.

As shown in FIG. 8A and FIG. 8B, memory device 800 can include three adjacent conductive contacts 665_{A}, 665_{B}, and 665_{C}. As shown in FIG. 8B, conductive contact 665_{B} can surround conductive contact 665_{A}. Conductive contact 665_{C} can surround conductive contact 665_{B}. FIG. 8A shows an example of six conductive contacts coupled to six respective control gates associated with signals WL0₀ through WL5₀. Improvements and benefits of memory device 800 are similar to or the same as improvements and benefits of memory device 200 described above.

In another example, as shown in FIG. 8A and FIG. 8B, the conductive contact coupled to the control gate associated with signal WL0₀ is closer (in the Y-direction) to pillar (memory cell pillar) 550 than the conductive contact coupled to the control gate associated with signal WL1₀ and the conductive contact coupled to the control gate associated with signal WL2₀. In this example, the length of the conductive contact coupled to the control gate associated with signal WL0₀ is greater than the length of each of the conductive contact coupled to the control gate associated with signal WL1₀ and the conductive contact coupled to the control gate associated with signal WL2₀. Improvements and benefits of memory device 800 are similar to or the same as improvements and benefits of memory device 200 described above.

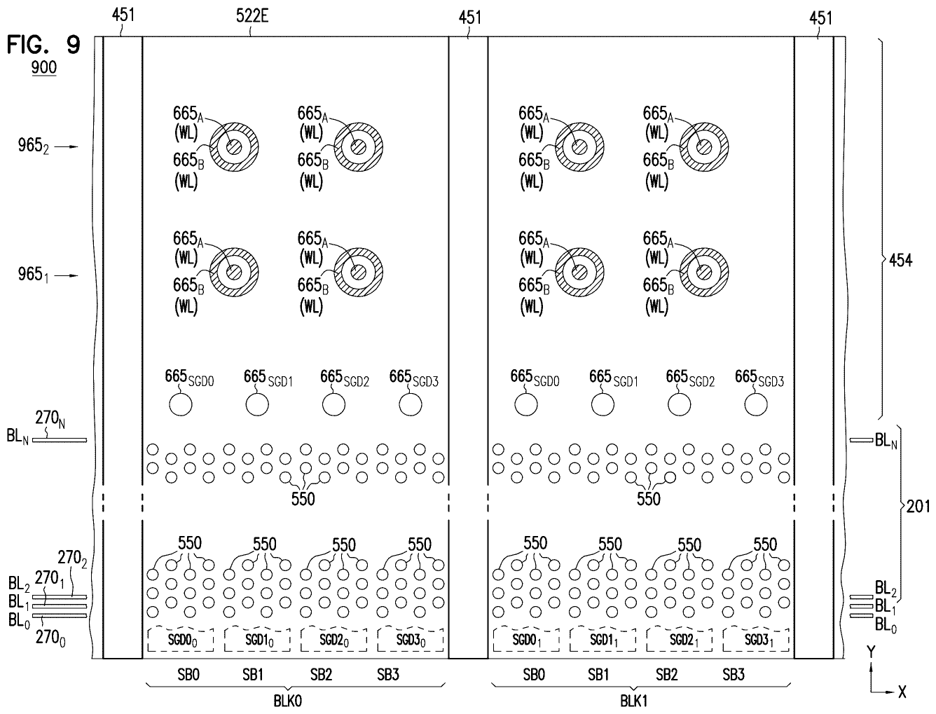

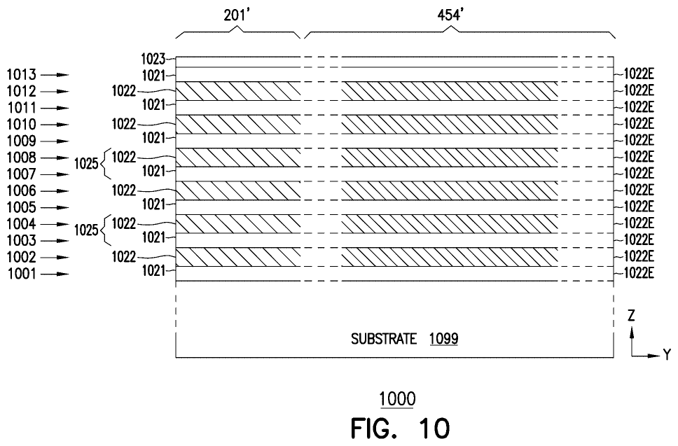

FIG. 9 shows a memory device 900 that can be a variation of memory device 200, according to some embodiments described herein. As shown in FIG. 9 and FIG. 6A, memory device 900 can include elements that are similar to or the same as the elements of memory device 200. For simplicity, descriptions of similar or the same elements between memory devices 200 and 900 are not repeated. As shown in FIG. 9, memory device 900 includes conductive contacts (e.g., conductive contacts 665_{A} and 665_{B}) like the conductive contacts of memory device 200 shown in FIG. 6A. Memory device 900 also includes conductive lines (like conductive lines 656 in FIG. 6B) coupled to the conductive contacts. For simplicity, such conductive lines are omitted from FIG. 9.

In comparison with memory device 200 (FIG. 6A), memory device 900 (FIG. 9) can include a higher number of conductive contacts (e.g., conductive contacts 665_{A} and 665_{B}) in region 454. The pattern (e.g., arrangement) of conductive contacts 665_{A} and 665_{B} in region 454 in FIG. 9 can also be different from the pattern of conductive contacts 665_{A} and 665_{B} in FIG. 6A. FIG. 9 shows an example where the conductive contacts (e.g., conductive contacts 665_{A} and 665_{B} and 665_{SGS0}) are formed in two rows 965₁ and 965₂ (side-by-side in the X-direction). Improvements and benefits of memory device 900 are similar to or the same as improvements and benefits of memory device 200 described above.

The above description with reference to FIG. 2 through FIG. 9 describes the structure of memory devices 200 and 900. Some or all of the structure of memory devices 200 and 900 can be formed using processes associated with the processes described below with reference to FIG. 10 through FIG. 24.

FIG. 10 through FIG. 24 show different views of elements during processes of forming a memory device 1000, according to some embodiments described herein. FIG. 10 shows a side view (e.g., cross-section) in the Y-Z direction of a portion of memory device 1000. The side view of memory device 1000 in FIG. 10 is similar to the side view of memory device 200 of FIG. 7A. In FIG. 10, the region included in memory array 201′ is similar to the region included in memory array 201 of memory device 200 in FIG. 6A and FIG. 7A. Region 454′ in FIG. 10 is similar to region 454 of memory device 200 in FIG. 6A and FIG. 7A.

The processes associated with FIG. 10 include forming dielectric materials (levels of dielectric materials) 1021 and dielectric materials (levels of dielectric materials) 1022 over substrate 1099. Dielectric materials 1021 can include silicon dioxide. Dielectric materials 1022 can include silicon nitride. The processes associated with FIG. 10 can include forming a dielectric material 1023 over dielectric materials 1021 and 1022. Examples of dielectric material 1023 include carbon nitride, silicon dioxide, or other dielectric materials.

As shown in FIG. 10, memory device 1000 can include levels 1001 through 1013, which are physical levels of the structure of memory device 1000. Dielectric materials (e.g., silicon dioxide) 1021 can be formed on respective levels 1001, 1003, 1005, 1007, 1009, 1011, and 1013. Dielectric materials (e.g., silicon nitride) 1021 can be formed on levels 1002, 1004, 1006, 1008, 1010, and 1012 that are interleaved with respective levels 1001 through 1013.

Substrate 1099 is similar to (e.g., can correspond to) substrate 599 of memory device 200 shown in FIG. 5A and FIG. 7A. Dielectric materials 1021 and 1022 can be sequentially formed one material after another over substrate 1099 in an interleaved fashion, such that dielectric materials 1021 can be interleaved with dielectric materials 1022. As shown in FIG. 10, dielectric materials 1021 and 1022 can include respective edges 1022E. Edges 1022E can be aligned (e.g., vertically aligned) with each other in the Z-direction. As shown in FIG. 10, dielectric materials 1021 and 1022 can form tiers (tiers of materials) 1025. Only two tiers 525 are labeled for simplicity. Tiers 1025 are located one over another in the Z-direction. Each tier 1025 can include a respective level of dielectric material 1021 and a respective level of dielectric material 1022. In levels 1001 through 1013, distance from one level to the next immediate level can correspond to the thickness (in the Z-direction) of one tier 1025.

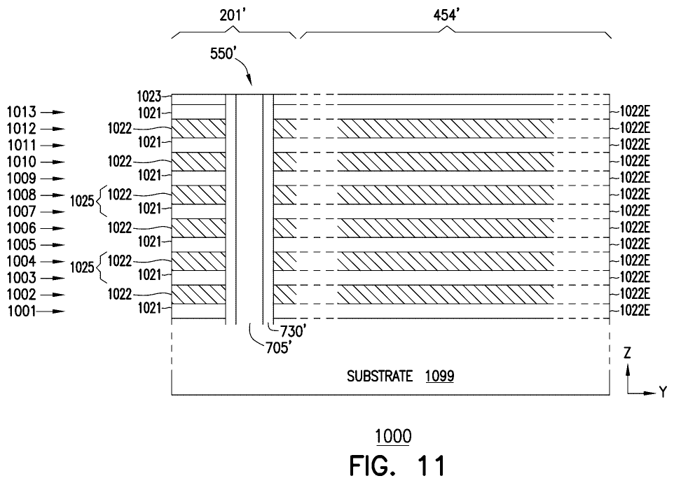

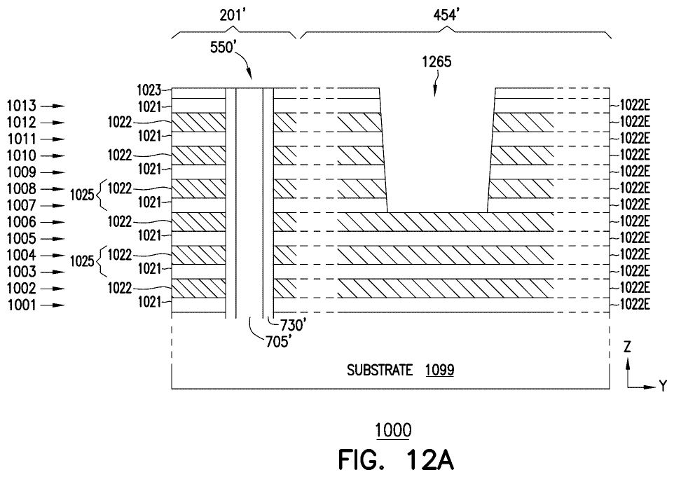

FIG. 11 shows memory device 1000 after a pillar (memory cell pillars) 550′ including structure 730′ and a dielectric material 705′ are formed. Pillar 550′, structure 730′, and dielectric material 705′ are similar to (e.g., can correspond to) pillar 550, structure 730, and dielectric material 705, respectively, of memory device 200 of FIG. 7A. Pillar 550′ is associated with a string of memory cells (not labeled in FIG. 11) like memory cells 210, 211, 212, and 213 of pillar 550 of memory device 200 of FIG. 7A. Although not shown in FIG. 11, the processes associated with FIG. 11 also form other memory cell pillars (like pillar 550′) and associated memory cells of the region included in memory array 201′ of memory device 1000.

In FIG. 11, forming pillar 550′ can include removing (exhuming) dielectric materials 1021 and 1022 at the location of pillar 550′ to form an opening (e.g., hole, not labeled) at the location of pillar 550′, and then forming pillars 550′ (which include structure 730′ and dielectric material 705′) in the location of the opening.

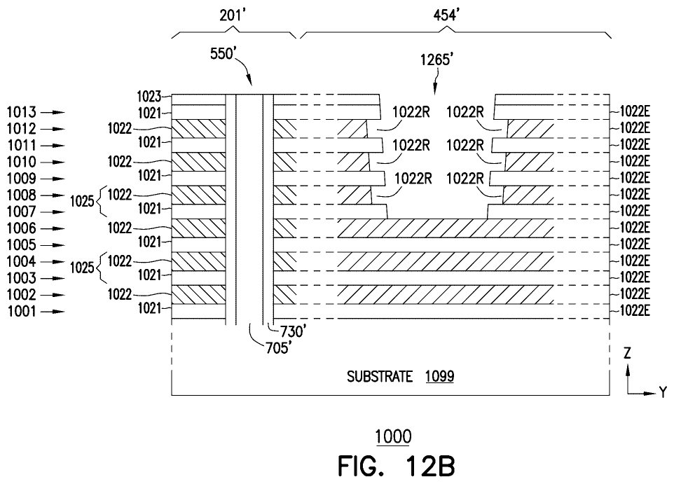

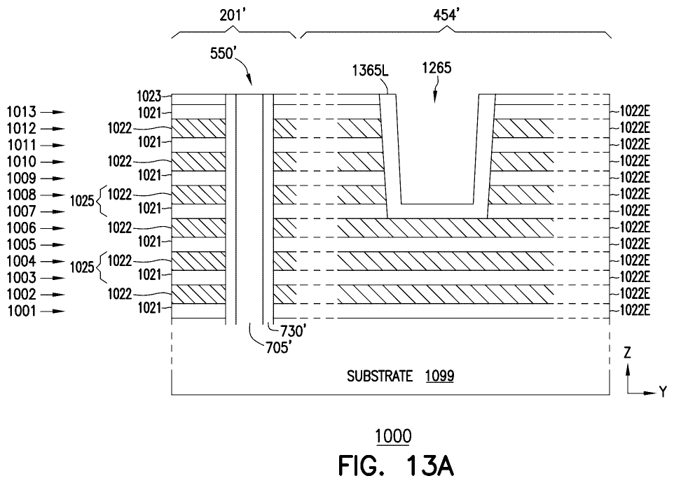

FIG. 12A shows memory device 1000 after an opening (e.g., a hole) 1265 is formed. Forming opening 1265 can include removing (e.g., patterning) a portion of dielectric material 1023 the location of opening 1265, then removing a portion of dielectric material 1021 and 1022 at opening 1265. Although not shown in FIG. 12A, the processes associated with FIG. 12A also form other openings like opening 1265 in region 454′. Opening 1265 can be called a contact opening at which multiple conductive contacts can be formed, as described below.

FIG. 12B shows an alternative process that includes forming an opening 1265′ with processes that further remove respective portions of dielectric materials (e.g., silicon nitride) 1022 at locations 1022R. As shown in FIG. 12B, opening 1265′ can have a different structure (e.g., different shape of the side walls) relative to the structure of opening 1265 in FIG. 12A. In FIG. 12B, removing respective portions of dielectric materials 1022 at locations 1222 can increase the effective width of dielectric isolation (thereby improving electrical isolation) between a particular conductive contact (e.g., like conductive contact 665_{B} of FIG. 7F) formed in opening 1265′ and adjacent control gates that are not coupled to that particular conductive contact.

In subsequent processes of forming memory device 1000, multiple conductive contacts (e.g., two conductive contacts similar to conductive contact 665_{A} and 665_{B} in FIG. 7A) associated with multiple control gates of memory device 1000 can be formed at the location of opening 1265 in FIG. 12A (or alternatively in the location of opening 1265′ in FIG. 12B).

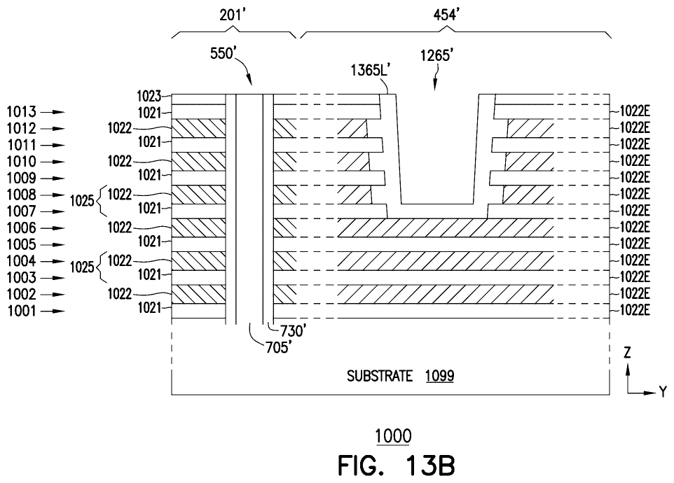

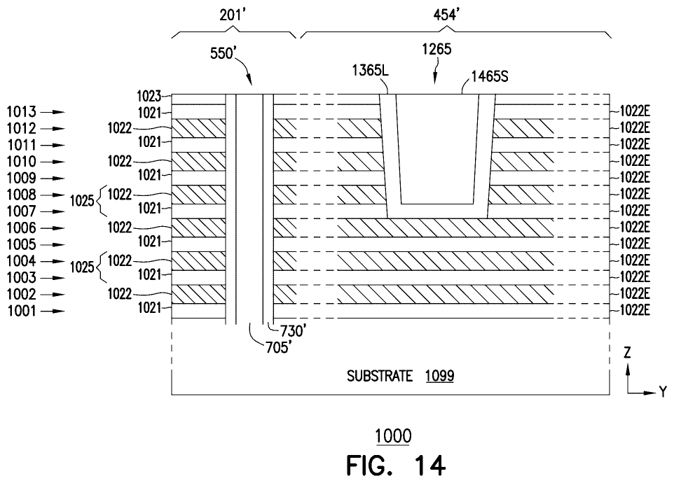

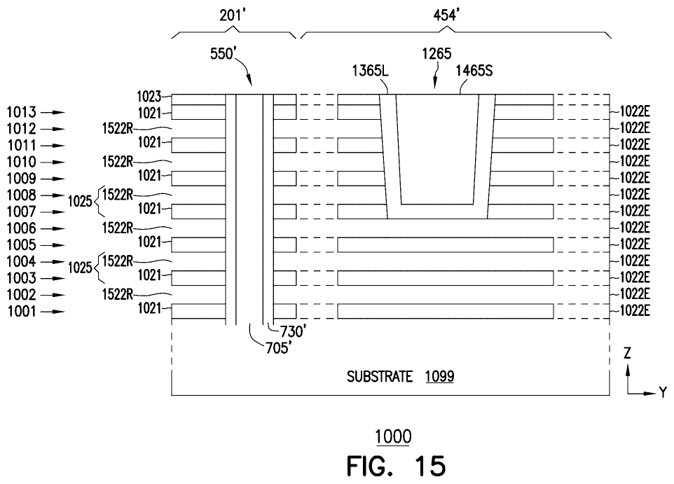

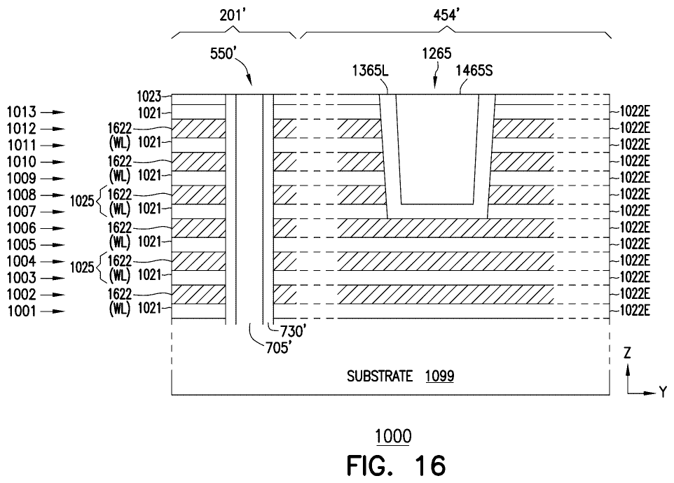

FIG. 13A shows memory device 1000 after a dielectric material 1365L is formed in opening 1265. Dielectric material 1365L can include silicon dioxide or other dielectric materials. Dielectric material 1365L can be a relatively thin material that covers side walls and bottom of opening 1265 (as shown in FIG. 13A).

FIG. 13B shows an alternative process that includes forming dielectric material 1365L′ in the alternative structure of memory device 1000 of FIG. 12B.

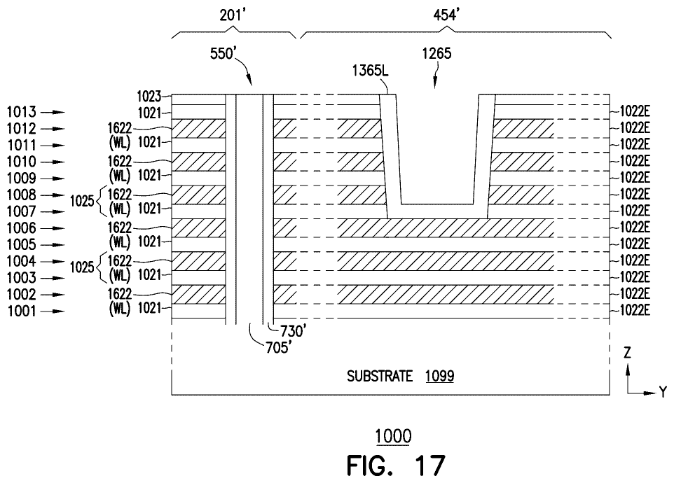

FIG. 14 shows memory device 1000 after a material (or materials) 1465S is formed (e.g., filled) in opening 1265. In subsequent processes of forming memory device 1000, material 1465S can be removed from opening 1265. Thus, material 1465S can be called a sacrificial material. An example of material 1465S can include carbon or other materials. Forming material 1465S can include forming a material (e.g., silicon dioxide, carbon, or other materials) in opening 1265. A chemical mechanical polishing (CMP) process can be performed after material 1465S is formed.

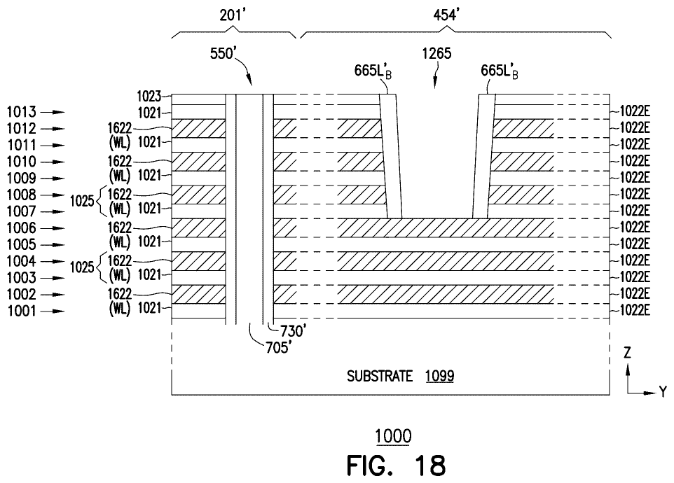

FIG. 15 shows memory device 1000 after dielectric materials 1022 of FIG. 14 are removed (e.g., exhumed) from locations 1522R (FIG. 15). Locations 1522R in FIG. 15 are voids (empty spaces) that were occupied by dielectric materials 1022 (FIG. 14). In subsequent processes (FIG. 16), conductive materials can be formed in locations 1522R to form respective control gates of memory device 1000.

FIG. 16 shows memory device 1000 after conductive materials (levels of conductive materials) 1622 are formed in locations 1522R of FIG. 15. Conductive materials 1622 can be similar to (or the same as) conductive materials 522 of memory device 200 (FIG. 5A and FIG. 7A).

In FIG. 16, conductive materials 1622 (e.g., levels of conductive materials 1622 in respective levels 1002, 1004, 1006, 1008, 1010, and 1012 can form respective control gates (associated with signals WL) of memory device 1000. The control gates associated with signals WL can be similar to the control gates associated with signals WL0₀, WL1₀, WL2₀, and WL3₀ of memory device 200 of FIG. 7A.

FIG. 17 shows memory device 1000 after material (sacrificial material) 1465S is removed from opening 1265.

FIG. 18 shows memory device 1000 after a dielectric liner 665L′_{B} is formed. Forming dielectric liner 665L′_{B} can include removing (e.g., using a punch process to remove) a portion (e.g., bottom portion) of dielectric material 1365L. As shown in FIG. 18 a portion of one of conductive materials 1622 (e.g., the conductive material 1622 on level 1006) can be exposed at opening 1265.

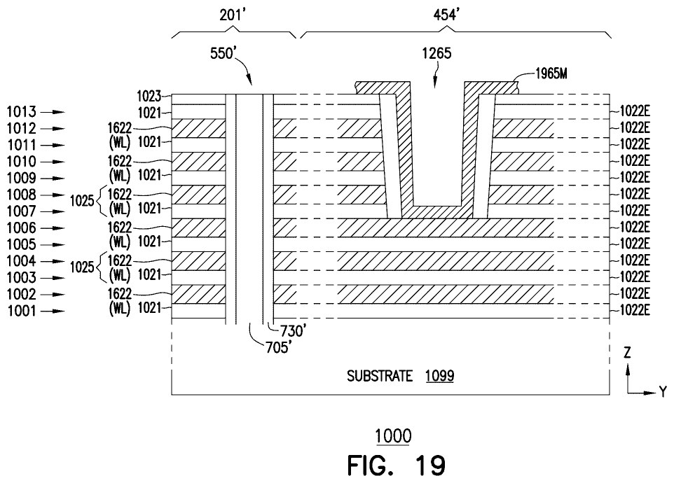

FIG. 19 shows memory device 1000 after a conductive material (or conductive materials) 1965M is formed in opening 1265. Conductive material 1965M can be formed adjacent (e.g., formed on) the side wall (e.g., an inner side wall, not labeled) of dielectric liner 665L′_{B}. Conductive material 1965M can also be formed over (e.g., formed on) and contacting conductive material 1622 on level 1006 that was exposed at opening 1265 in FIG. 18.

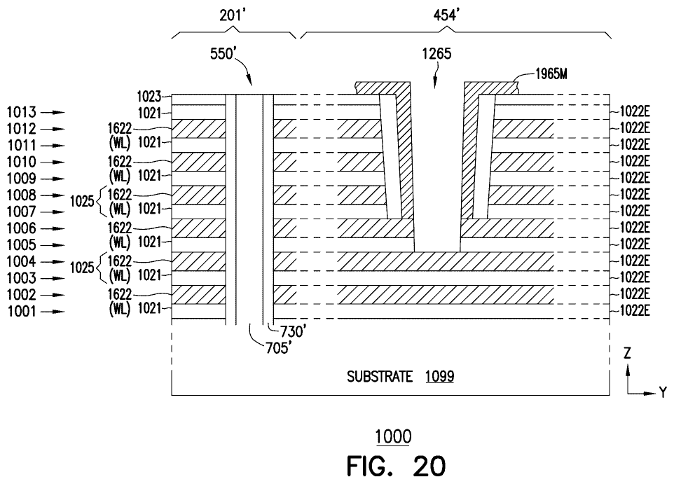

FIG. 20 shows memory device 1000 after a portion (e.g., bottom portion) of conductive material 1965M is removed (e.g., punched). As shown in FIG. 20, a portion of one of conductive materials 1622 (e.g., the conductive material 1622 on level 1004) can be exposed at opening 1265. In an alternative process, the process (e.g., punch process) of removing the portion of conductive material 1965M in FIG. 20 can be stopped at one of dielectric materials 1021 (e.g., the dielectric material 1021 on level 1005), such that a portion of one of conductive materials (e.g., of the control gates) 1622 can still be covered by one of dielectric material 1021 (e.g., the dielectric material 1021 on level 1005).

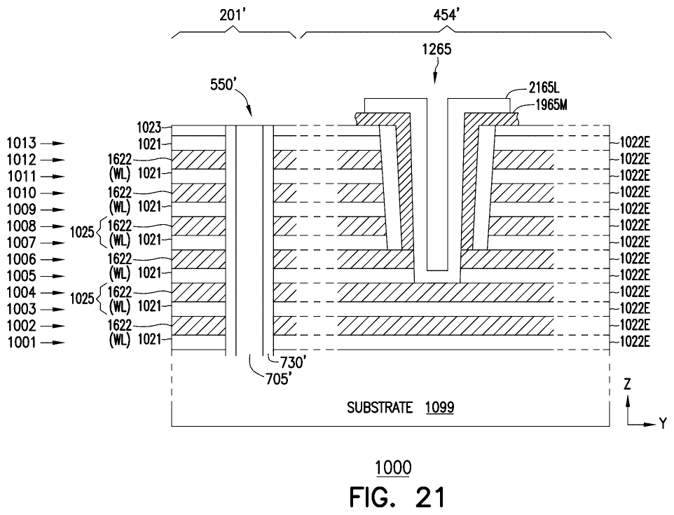

FIG. 21 shows memory device 1000 after a dielectric material 2165L is formed in opening 1265. Dielectric material 2165L can include silicon dioxide or other dielectric materials. Dielectric material 2165L can be a relatively thin material that covers the side wall (not labeled) of conductive material 1965M.

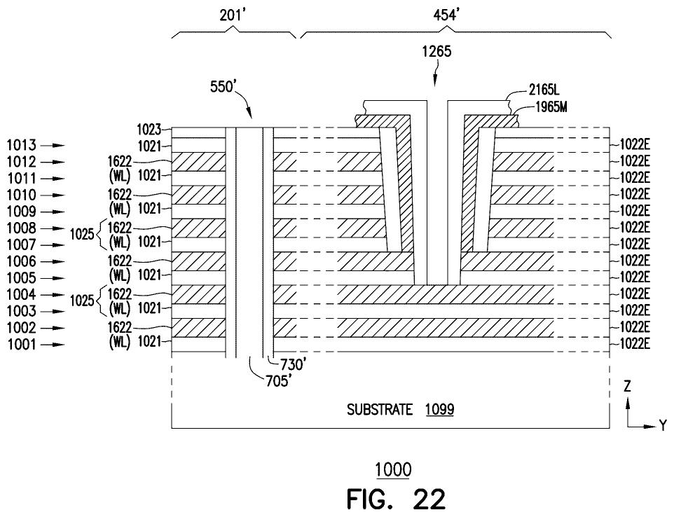

FIG. 22 shows memory device 1000 after a portion (e.g., bottom portion) of dielectric material 2165L is removed (e.g., punched). As shown in FIG. 22, a portion of one of conductive materials 1622 (e.g., the conductive material 1622 on level 1004) can be exposed at opening 1265.

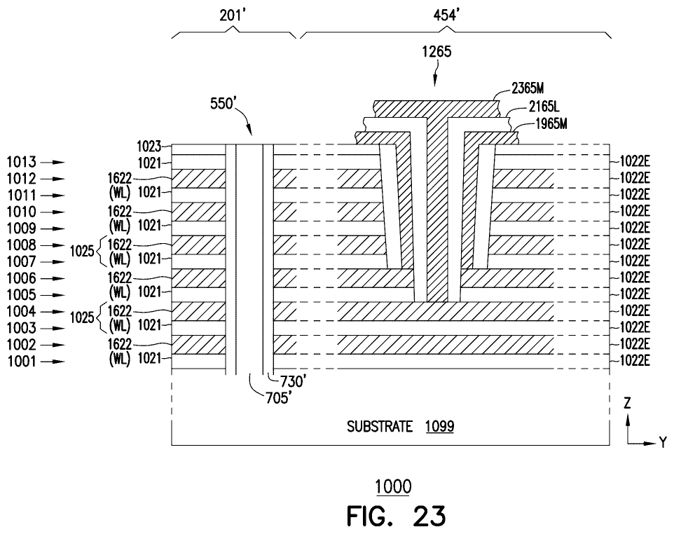

FIG. 23 shows memory device 1000 after conductive material 2365M is formed in opening 1265. Conductive material 2365M can be formed adjacent the side wall (e.g., inner sidewall, not labeled) of dielectric material 2165L, such that conductive material 2365M may fill the space surrounded by dielectric material 2165L. Conductive material 2365M can be formed over (e.g., formed on) and contacting conductive material 1622 that was exposed at opening 1265 in FIG. 22.

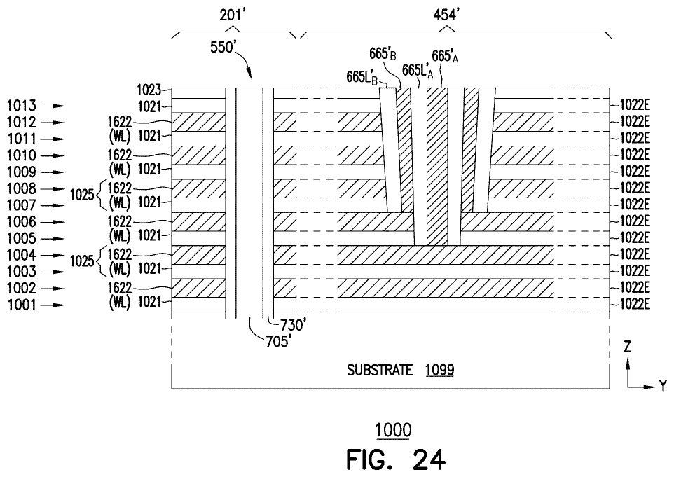

FIG. 24 shows memory device 1000 after conductive contacts 665′_{A} and 665′_{B} and dielectric liner 665L′_{A} are formed. Forming conductive contacts 665′_{A} and 665′_{B} and dielectric liner 665L′_{A} can include removing (e.g., using a CMP process to remove) a portion (e.g., top portion) of each of conductive material 1965M, conductive material 2365M, and dielectric material 2165L, respectively, in FIG. 23.

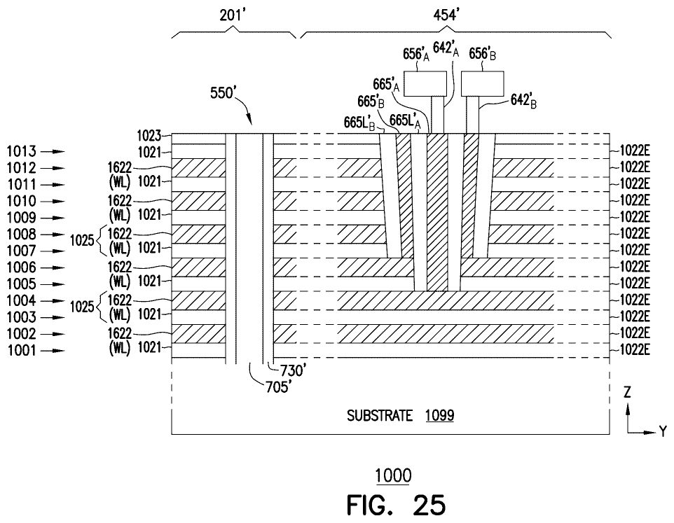

FIG. 25 shows memory device 1000 after conductive connections 642′_{A} and 642′_{B} and conductive lines 656′_{A} and 656′_{B} are formed. As shown in FIG. 25, the elements of memory device 1000 can be similar to those of the elements of memory device 200 of FIG. 7A. Thus, improvements and benefits of memory device 1000 are similar to or the same as improvements and benefits of memory device 200 described above including improvement in at least one of device area, yield, cost, performance, and reliability of memory device 1000.

The processes of forming memory device 1000 described above with reference to FIG. 10 through FIG. 25 can include other processes to form a complete memory device (e.g., memory device 1000). Such processes are omitted from the above description so as not to obscure the subject matter described herein.

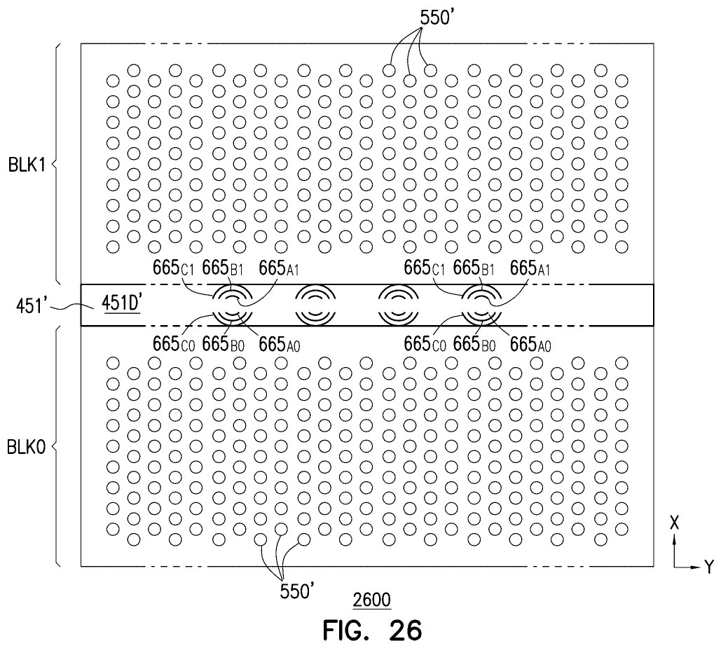

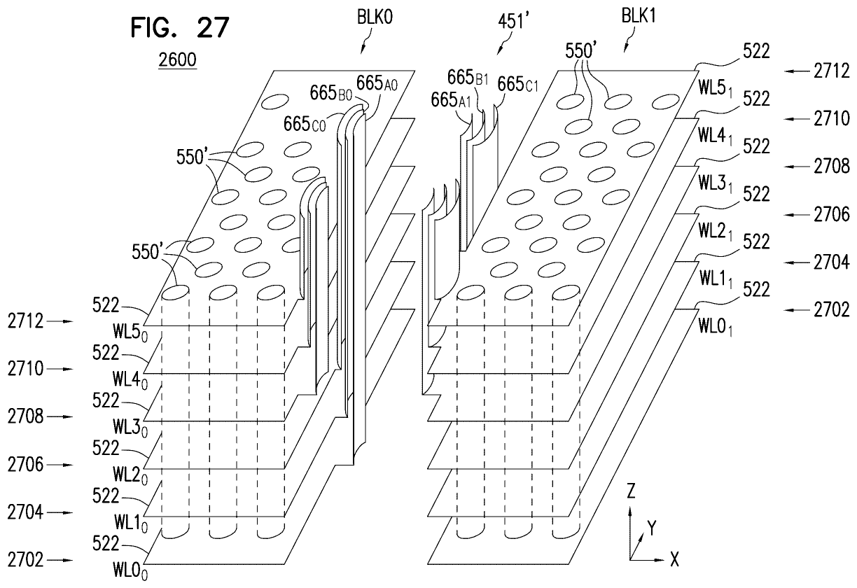

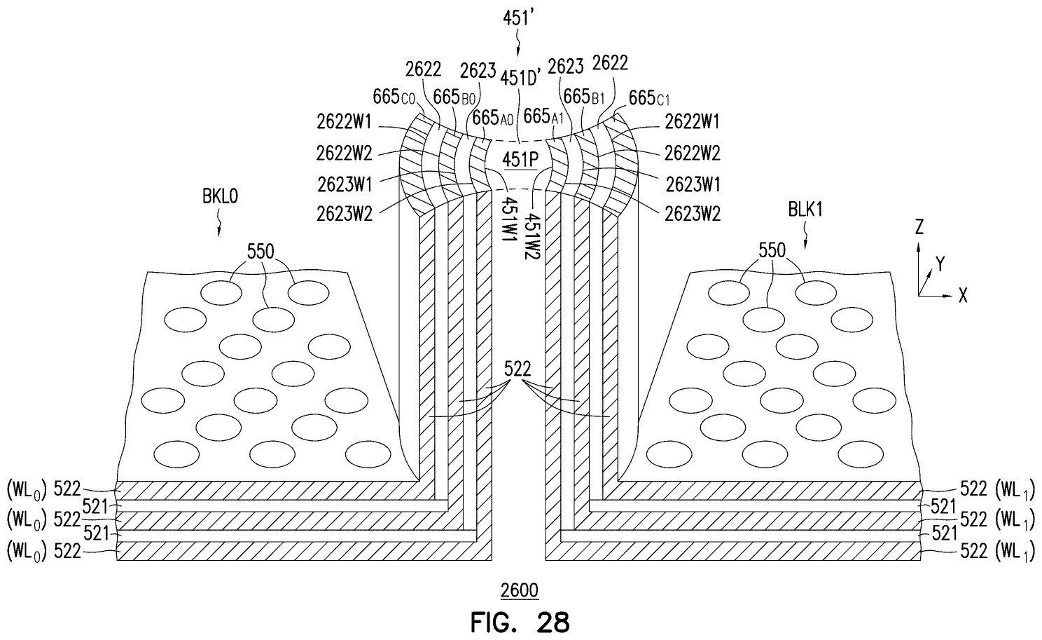

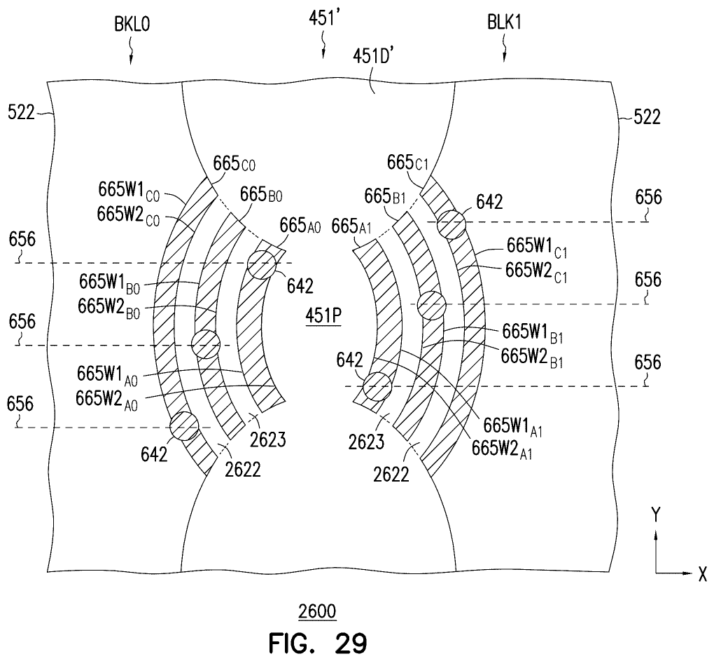

FIG. 26, FIG. 27, FIG. 28, and FIG. 29 show different views of memory device 2600, according to some embodiments described herein. FIG. 26 shows a top view of a structure of memory device 2600. FIG. 27 shows a simple perspective view representing a portion of the structure of memory device 2600. FIG. 28 shows another perspective view representing a portion of the structure of memory device 2600. FIG. 29 shows a top of view of a portion of memory device 2600 of FIG. 28. Memory device 2600 includes elements similar to or the same as the elements of memory device 200 and 1000 described above. For example, as shown in FIG. 26, memory device 2600 can include pillars (memory cell pillars) 550′ (shown in top view) in respective blocks BLK0 and BLK1, and dielectric structure 451′ (which includes a dielectric material 451D′) between blocks BLK0 and BLK1. For simplicity, similar or the same elements between memory devices 200, 1000, and 2600 are given the same labels (or alternatively labels having the same numerical portions) and their detailed descriptions are not repeated.

As shown in FIG. 26 through FIG. 29, memory device 2600 can include conductive contacts 665_{A0}, 665_{B0}, 665_{C0}, 665_{A1}, 665_{B1}, and 665_{C1} located in between blocks BLK0 and BLK1 in the region that includes dielectric structure 451′. In FIG. 27, FIG. 28, and FIG. 29, conductive contacts 665_{A0}, 665_{B0}, and 665_{C0} are included in block BLK0 to form an electrical connection with (to contact) respective control gates (associated with signals WL0₀, WL1₀, WL2₀, WL3₀, WL4₀, and WL5₀ in FIG. 27) in block BLK0. In FIG. 28, the control gates associated with signal WL₀ correspond to some of the control gates associated with signals WL1₀, WL2₀, WL3₀, WL4₀, and WL5₀ of FIG. 27.

In FIG. 27, FIG. 28, and FIG. 29, conductive contacts 665_{A1}, 665_{B1}, and 665_{C1} are included in block BLK1 to form an electrical connection with (to contact) respective control gates (associated with signals WL0₁, WL1₁, WL2₁, WL3₁, WL4₁, and WL5₁) in block BLK1. In FIG. 28, the control gates associated with signals WL₁ correspond to some of the control gates associated with signal WL0₁, WL2₁, WL3₁, WL4₁, and WL5₁ of FIG. 27.

The conductive contacts of block BLK0 (e.g., conductive contacts 665_{A0}, 665_{B0}, and 665_{C0} located in block BLK0) are separated (electrically isolated) from the conductive contacts of block BLK1 (e.g., conductive contacts 665_{A1}, 665_{B1}, and 665_{C1} located in block BLK1). FIG. 26 shows an example of four groups of conductive contacts with three conductive contacts in each group (for a total of 12 conductive contacts). For example, FIG. 26 shows four groups of conductive contacts 665_{A0}, 665_{B0}, and 665_{C0} in block BLK0, and four groups of conductive contacts 665_{A1}, 665_{B1}, and 665_{C1} in block BLK1. However, memory device 2600 can include more than four groups of conductive contacts for a total of up to hundreds of conductive contacts (or more than hundreds of conductive contacts). The number of conductive contacts (like conductive 665_{A0}, 665_{B0}, and 665_{C0}) in a respective block can be equal to the number of the control gates of the respective block of memory device 2600. Further, FIG. 26 shown an example of three conductive contacts adjacent each other in a group. However, the number of conductive contacts in a group can be different from three.

The functions of conductive contacts 665_{A0}, 665_{B0}, 665_{C0}, 665_{A1}, 665_{B1}, and 665_{C1} are similar to the functions of conductive contacts 665_{A} and 665_{B} of memory devices 200 and 1000 described above. The conductive contacts of block BLK0 (e.g., conductive contacts 665_{A0}, 665_{B0}, and 665_{C0}) allow signals (e.g., word line signals WL0₀, WL1₀, WL2₀, WL3₀, WL4₀, and WL5₀, shown in FIG. 27) to be provided to respective control gates of block BLK0 through the conductive contacts of block BLK0. The conductive contacts of block BLK1 (e.g., conductive contacts 665_{A1}, 665_{B1}, and 665_{C1}) allow signals (e.g., word line signals WL0₁, WL1₁, WL2₁, WL3₁, WL4₁, and WL5₁, shown in FIG. 27) to be provided to respective control gates of block BLK1 through the conductive contacts of block BLK1.

In FIG. 27, conductive materials 522 on respective levels 2702, 2704, 2706, 2708, 2710, and 2712 are similar to conductive materials 522 on respective levels 501 through 512 of FIG. 7A. For simplicity, dielectric materials (e.g., similar to dielectric materials 521 in FIG. 7A) between conductive materials 522 are not shown in FIG. 27. Conductive materials 522 can form respective control gates in respective blocks BLK0 and BLK1 of memory device 2600.

As shown in FIG. 27, each group of conductive contacts (e.g., three conductive contacts) 665_{A0}, 665_{B0}, and 665_{C0} in block BLK0 can contact (can form an electrical connection with) control gates (e.g., three control gates WL0₀, WL1₀, WL2₀ or WL3₀, WL4₀, and WL5₀,) of an associated group of control gate in block BLK0. Similarly, each group of conductive contacts (e.g., three conductive contacts) 665_{A1}, 665_{B1}, and 665_{C1} in block BLK1 can contact (can form an electrical connection with) control gates (e.g., three control gates WL0₁, WL1₁, and WL2₁ or WL3₁, WL4₁, and WL5₁,) of an associated group of control gate in block BLK1.

As shown in FIG. 26, dielectric structure 451′ can include a length in the Y-direction, which is a direction perpendicular to a direction (e.g., the X-direction) from conductive contact 665_{A0} to conductive contact 665_{A1}, from conductive contact 665_{B0} to conductive contact 665_{B1}, or from conductive contact 665_{C0} to conductive contact 665_{C1}. As shown in FIG. 28, dielectric structure 451′ can include a portion 451P, which can include side walls 451W1 and 451W2.

As shown in FIG. 28, spacers 2622 and 2623 associated with conductive contacts 665_{A0}, 665_{B0}, and 665_{C0} in block BLK0 can include respective side walls (e.g., vertical curved side walls) 2622W1, 2622W2, 2623W1, and 2623W2. Spacers 2622 and 2623 associated with conductive contacts 665_{A1}, 665_{B1}, and 665_{C1} in block BLK1 can include respective side wall (e.g., vertical curved side walls) 2622W1, 2622W2, 2623W1, and 2623W2, which are different from 2622W1, 2622W2, 2623W1, and 2623W2 in block BLK0.

As shown in FIG. 29, conductive contacts 665_{A0}, 665_{B0}, and 665_{C0} can include respective side walls (e.g., vertical curved side walls) 665W1_{A0}, 665W2_{A0}, 665W1_{B0}, 665W2_{B0}, 665W1_{C0} and 665W2_{C0}. Conductive contacts 665_{A1}, 665_{B1}, and 665_{C1} can include respective side walls (e.g., vertical curved side walls) 665W1_{A1}, 665W2_{A1}, 665W1_{B1}, 665W2_{B1}, 665W1_{C1} and 665W2_{C1}.

Conductive contacts 665_{A0}, 665_{B0}, and 665_{C0} and spacers 2622 and 2623 are adjacent each other (e.g., contacting each other) in ways shown in FIG. 28 and FIG. 29. For example, the side wall of one structure (e.g., one of conductive contacts 665_{A0}, 665_{B0}, and 665_{C0}) can be adjacent (e.g., can wrap) the side wall of an adjacent structure (e.g., one of spacers 2622 and 2623) in ways shown in FIG. 28 and FIG. 29.

As shown in FIG. 28, conductive contacts 665_{A0}, 665_{B0}, and 665_{C0} are adjacent each other in the X-direction. Conductive contacts 665_{A0}, 665_{B0}, and 665_{C0} can have different lengths (unequal lengths) in the Z-direction. Similarly, 665_{A1}, 665_{B1}, and 665_{C1} are adjacent each other in the X-direction. Conductive contacts 665_{A1}, 665_{B1}, and 665_{C1} can have different lengths (unequal lengths) in the Z-direction. As shown in FIG. 28, conductive contacts 665_{A0}, 665_{B0}, 665_{C0}, and 665_{A1}, 665_{B1}, and 665_{C1}, and the control gates (associated with signal gates WL₀ and WL₁) can be formed from the same conductive material (or conductive materials) 522.

As shown in FIG. 29 (top view), memory device 2600 can include conductive connections 642 coupled to respective conductive contacts 665_{A0}, 665_{B0}, and 665_{C0} and respective conductive lines 656 in block BLK0 and respective conductive contacts 665_{A1}, 665_{B1}, and 665_{C1} in block BLK1. Conductive contacts 665_{A0}, 665_{B0}, and 665_{C0} can be separated (electrically isolated) from each other by respective spacers 2622 and 2623. Conductive contacts 665_{A1}, 665_{B1}, and 665_{C1} can be separated (electrically isolated) from each other by respective spacers (dielectric spacers) 2622 and 2623. An example material for spacers 2622 and 2623 include silicon dioxide. Spacers 2622 and 2623 can be called dielectric spacers (or alternatively, dielectric liners).

Improvements and benefits of memory device 2600 are similar to or the same as improvements and benefits of memory device 200 described above.

The above description with reference to FIG. 26 through FIG. 29 describes the structure of memory device 2600. Some or all of the structure of memory device 200 can be formed using processes associated with the processes described below with reference to FIG. 27 through FIG. 52.

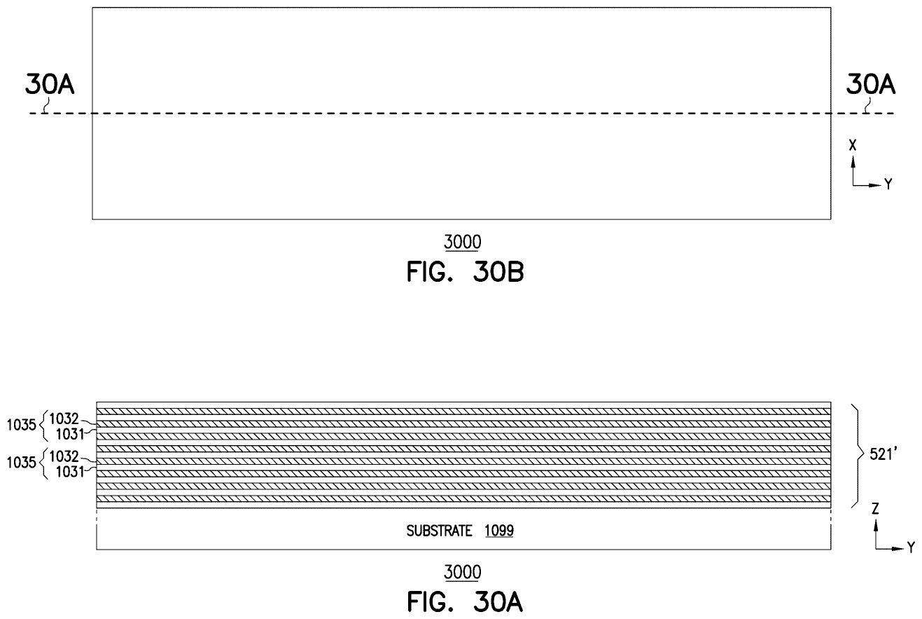

FIG. 30A through FIG. 52B show different views of elements during processes of forming a memory device 3000, according to some embodiments described herein. FIG. 30A shows a side view (e.g., cross-section) in the Y-Z direction of a portion of memory device 3000 at line 30A of FIG. 30B. FIG. 30B is a top view (in the X-Y direction) of a portion of memory device 3000.

The processes associated with FIG. 30A and FIG. 30B can include forming dielectric materials (levels of dielectric materials) 1031 and dielectric materials (levels of dielectric materials) 1032 over a substrate 1099. Dielectric materials 1031 and 1032 can be similar to or the same as dielectric materials 1021 and 1022 of FIG. 10. Dielectric materials 1031 can include silicon dioxide. Dielectric materials 1032 can include silicon nitride. Dielectric materials 1031 and 1032 can be sequentially formed one material after another over substrate 1099 in an interleaved fashion, such that dielectric materials 1031 can be interleaved with dielectric materials 1032.

As shown in FIG. 30A, dielectric materials 1031 and 1032 can form tiers (tiers of materials) 1035. Tiers 1035 are located one over another in the Z-direction. Each tier 1035 can include a respective level of dielectric material 1031 and a respective level of dielectric material 1032. As shown in FIG. 30A, tiers 1035 can be included in a deck 521′ of memory device 3600.

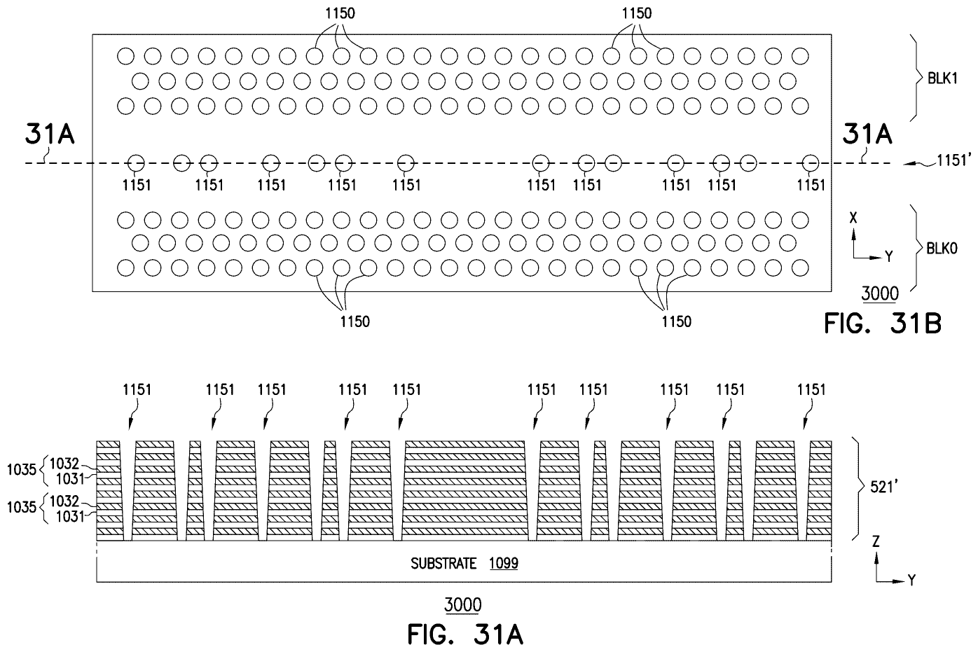

FIG. 31A and FIG. 31B show memory device 3000 after openings (e.g., holes) 1150 and 1151 are formed. Openings 1151 can be formed in region 1151′, which is between blocks BLK0 and BLK1. In subsequent processes of forming memory device 3000, conductive contacts (like conductive contacts 665_{A0}, 665_{B0}, 665_{C0}, 665_{A1}, 665_{B1}, and 665_{C1} of memory device 2600 of FIG. 26 through FIG. 29) can be formed in region 1151′.

As shown in FIG. 31B, openings 1150 can be formed in respective regions of memory device 3000 that includes blocks BLK0 and BLK1. In subsequent processes of forming memory device 3000, part of memory cell strings of memory device 3000 can be formed at the locations of respective openings 1150. FIG. 31B shows a small number of openings 1150 for simplicity. In reality, numerous openings 1150 can be formed.

Forming openings 1150 and 1151 can include removing (e.g., etching) a portion of dielectric materials 1031 and 1032 at the locations of openings 1150 and 1151. In FIG. 31B, region 1151′ is similar to the region of memory device 200 where dielectric structure 451 (FIG. 5 and FIG. 6) is located.

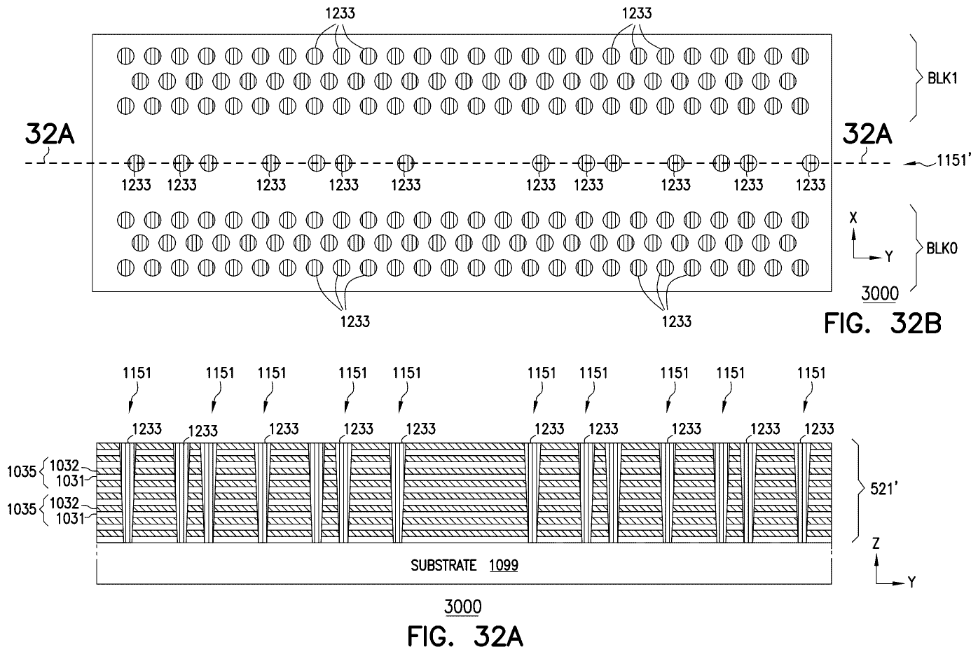

FIG. 32A and FIG. 32B show memory device 3000 after a material (or materials) 1233 is formed (e.g., filled) in openings 1150 and 1151. In subsequent processes of forming memory device 3000, material 1233 can be removed (e.g., removed at different times) from openings 1150 and 1151. Thus, material 1233 can be called a sacrificial material. An example of material 1233 can include carbon or other materials. Forming material 1233 can include forming a material (e.g., carbon) in openings 1150 and 1151. A chemical mechanical polishing (CMP) process can be performed after material 1233 is formed.

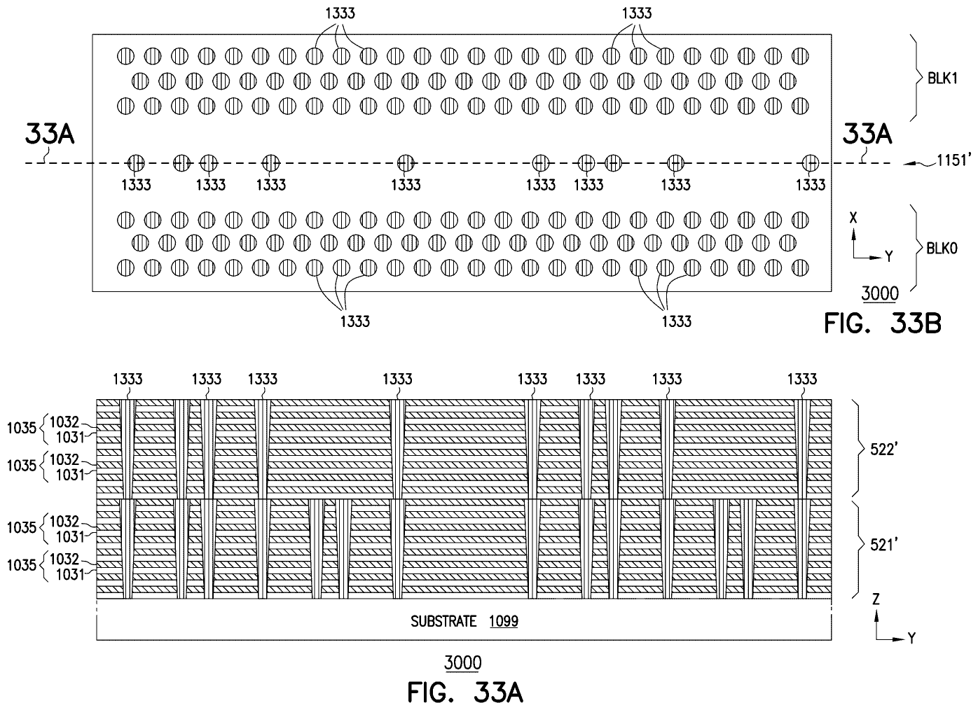

FIG. 33A and FIG. 33B show memory device 3000 after additional dielectric materials 1031 and dielectric materials 1032 (additional tiers) of deck 522′ are formed over deck 521′. Forming deck 522′ can be similar to forming deck 521′ described above. Thus, for simplicity, some of the processes (process steps) are not shown. For example, the processes associated with forming deck 522′ in FIG. 13A can include forming openings in dielectric materials 1031 and dielectric materials 1032 of deck 522′, then forming a material (e.g., sacrificial) 1333 (FIG. 33A) in the openings.

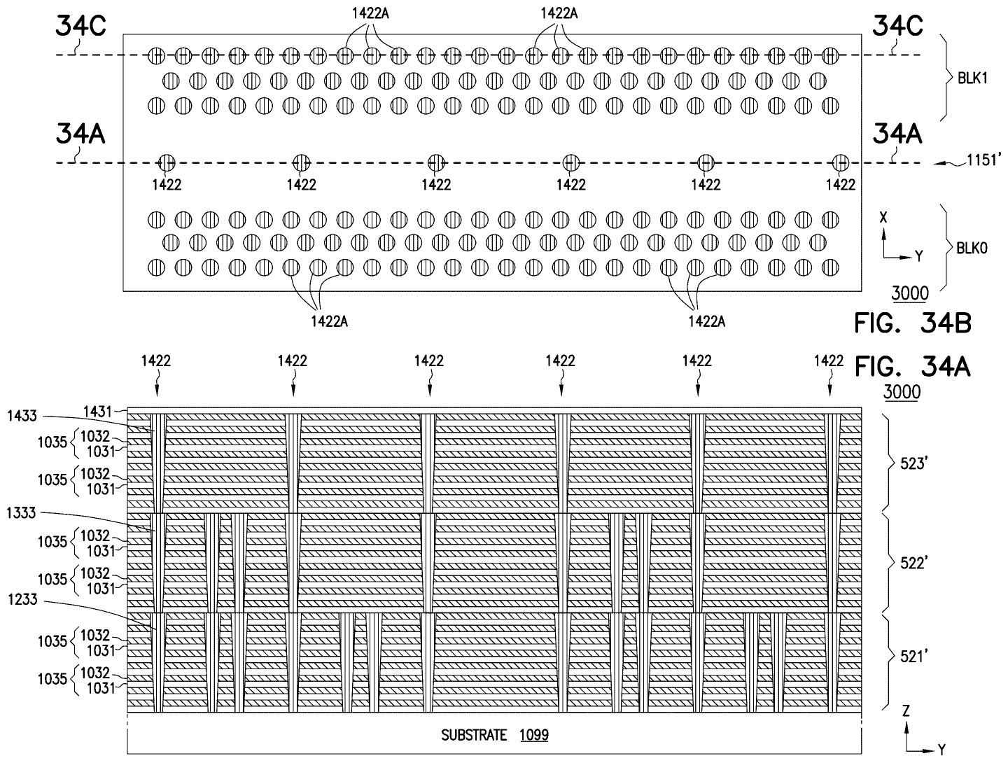

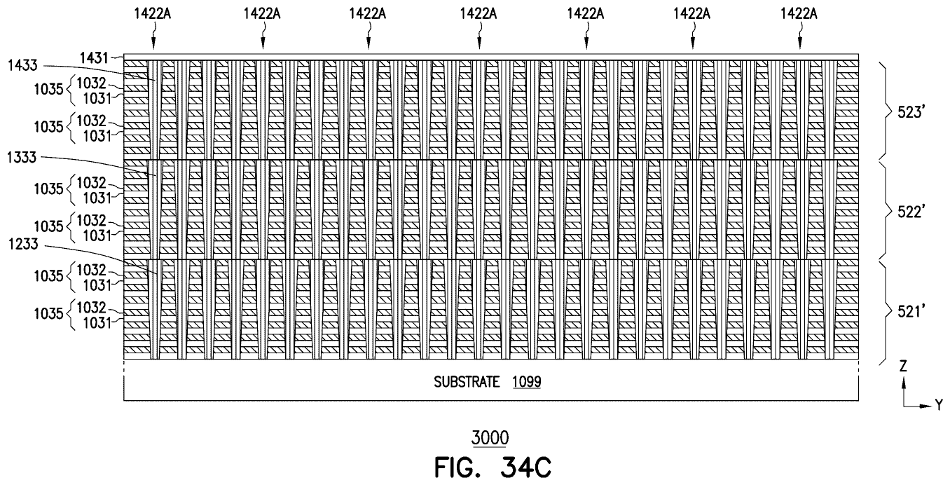

FIG. 34A, FIG. 34B, and FIG. 34C show memory device 3000 after additional dielectric materials 1031 and dielectric materials 1032 (additional tiers) of deck 523′ are formed over deck 522′, and pillars 1422 and 1422A are formed over decks 521′, 522′, and 523′. FIG. 34A and FIG. 34C show side views of memory device 3000 at lines 34A and 34C of FIG. 34B.

Forming deck 523′ in FIG. 34A can be similar to forming deck 521′ described above. Thus, for simplicity, some of the processes (process steps) are not shown. For example, the processes associated with forming deck 523′ in FIG. 34A can include forming openings in dielectric materials 1031 and dielectric materials 1032 of deck 523′, then forming a material (e.g., sacrificial) 1433 (FIG. 34A) in the openings. The processes associated with 34A, FIG. 34B, and FIG. 34C can include forming material 1431 over deck 523′.

Each of pillars 1422 and 1422A can include materials 1233, 1333, and 1433 in respective decks 521′, 522′, and 523′. Pillars 1422 can be formed in region 1151′ of decks 521′, 522′, and 523′. Pillars 1422A can be formed in the regions (memory array region) of blocks BLK0 and BLK1 of decks 521′, 522′, and 523′.

As shown in 34A, FIG. 34B, and FIG. 34C, pillars 1422 and 1422A can be formed in the same way and have the same profiles (e.g., same shape). However, pillars 1422 and 1422A can be formed for different purposes, as described below.

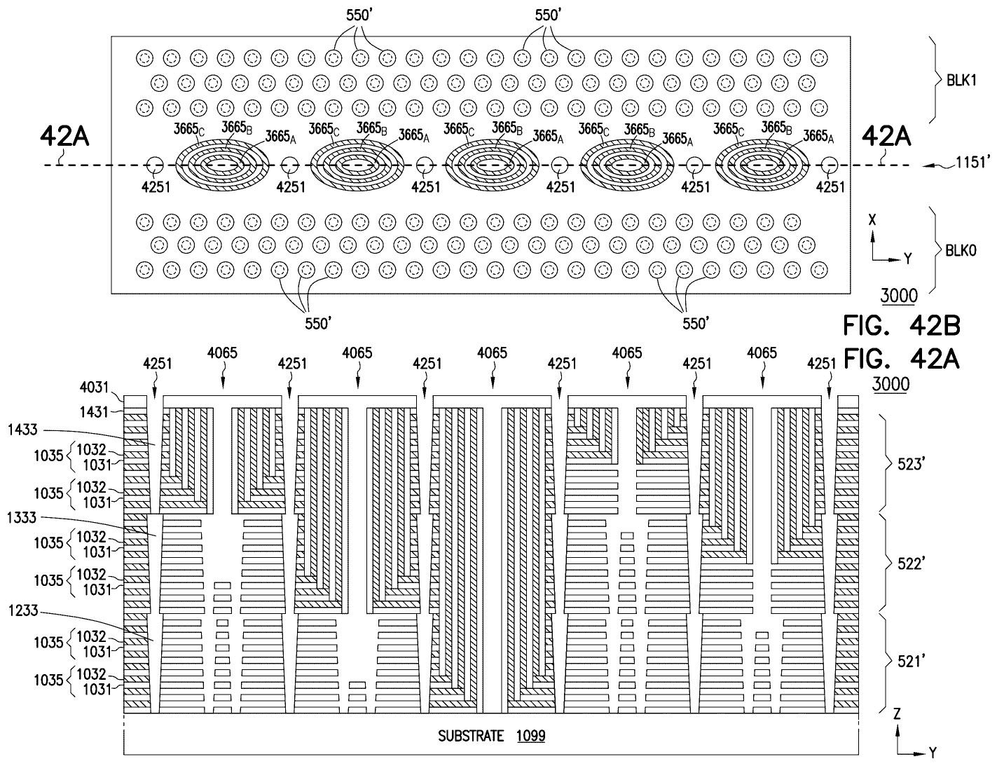

In subsequent processes associated with forming memory device 3000, materials 1233, 1333, and 1433 in pillars 1422 can be removed (in FIG. 42A and FIG. 42B) as part of forming conductive contacts of memory device 3000.

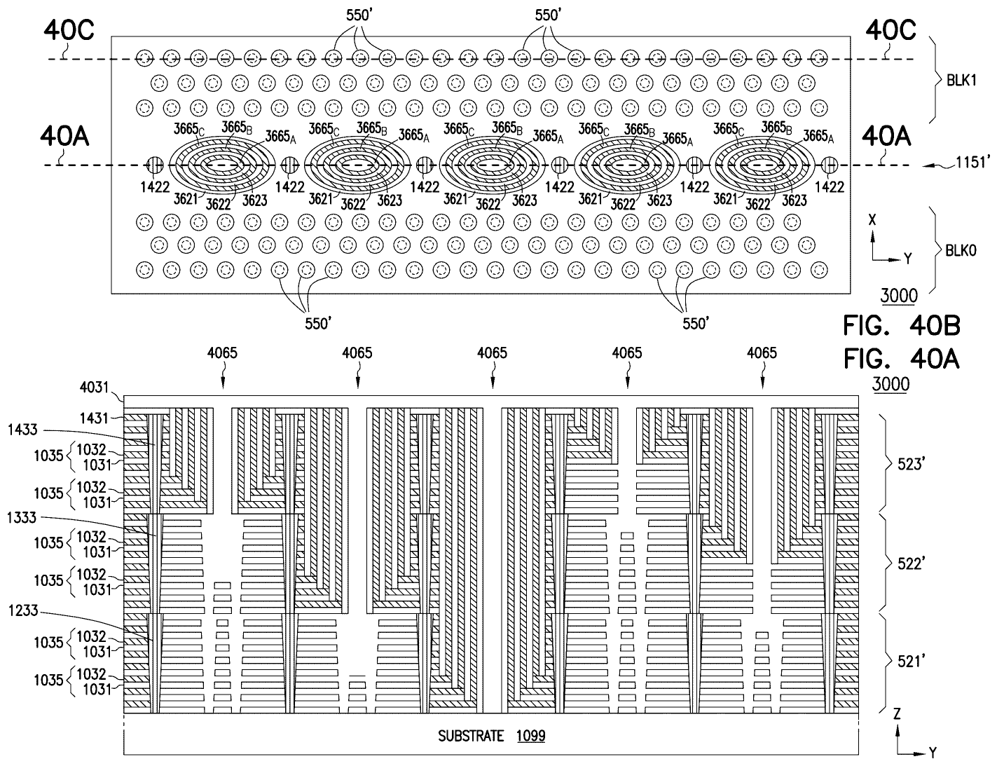

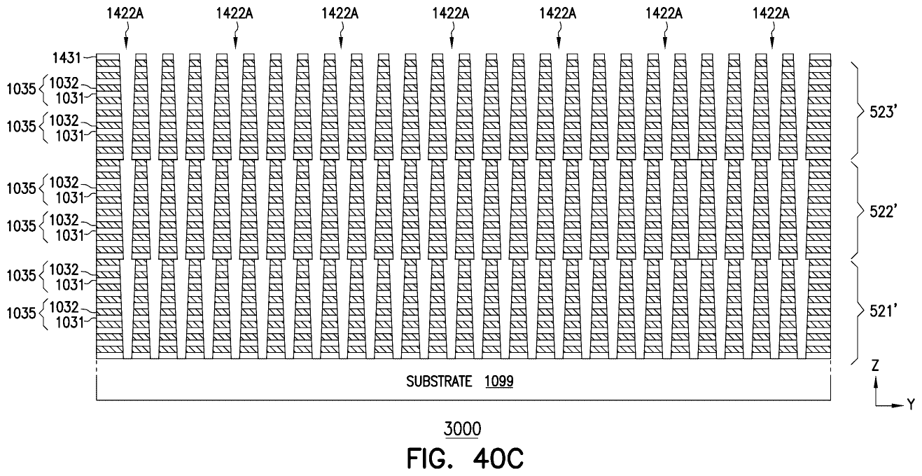

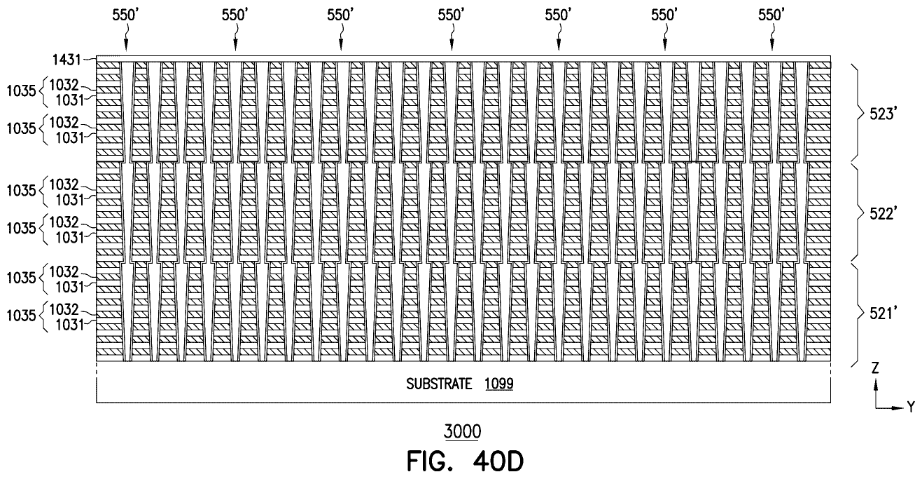

In subsequent processes associated with part of forming memory cells of memory device 3000 (as described below with reference to FIG. 40C and FIG. 40D), materials 1233, 1333, and 1433 in pillars 1422A of FIG. 34C can be removed to form memory cells and associated with pillars (memory cell pillars) of blocks BLK0 and BLK1 of memory device 3000.

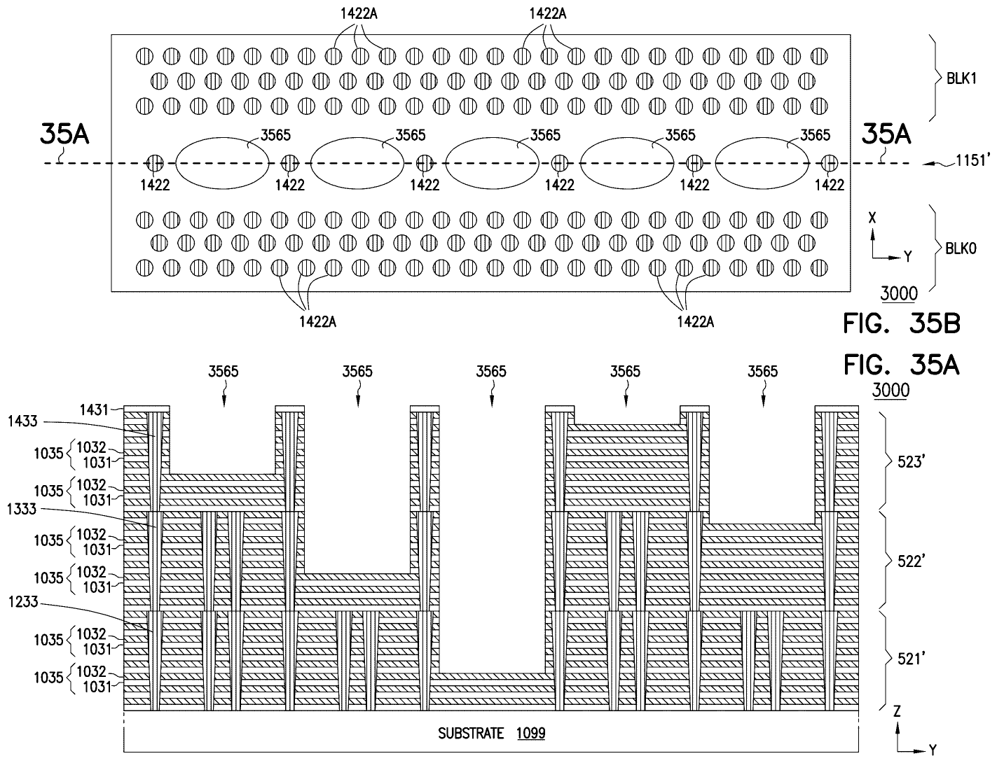

In the following processes associated with FIG. 35A through FIG. 40A and FIG. 40B, the materials (e.g., pillars 1422A) in the regions (e.g., memory array regions) of blocks BLK0 and BLK1 are covered (e.g., masked) while the processes are performed at region 1151′. Thus, materials (e.g., sacrificial materials) 1233, 1333, and 1433 formed in the regions of blocks BLK0 and BLK1 can remain (not be removed) while the processes are performed at region 1151′. In the processes associated with FIG. 40C and FIG. 40D, the regions (memory array regions) of blocks BLK0 and BLK1 can be uncovered (e.g., unmasked). After uncovering, memory cells and associated pillars (memory cell pillars) can be formed at the regions of block BLK0 and BLK1.

FIG. 35A and FIG. 35B show memory device 3000 after openings (e.g., holes) 3565 are formed. Openings 3565 can be called contact openings. Openings 3565 can be formed in region 1151′, which is between blocks BLK0 and BLK1. Forming openings 3565 can include removing a portion of dielectric materials 1031 and 1032 in region 1151′ at the locations of openings 3565. In subsequent processes of forming memory device 3000, conductive contacts (like conductive contacts 665_{A0}, 665_{B0}, 665_{C0}, 665_{A1}, 665_{B1}, and 665_{C1} of memory device 2600 of FIG. 26 through FIG. 29) and structures (e.g., dielectric contact structures 4065 in FIG. 40A and FIG. 40B) are formed at the locations of openings 3565.

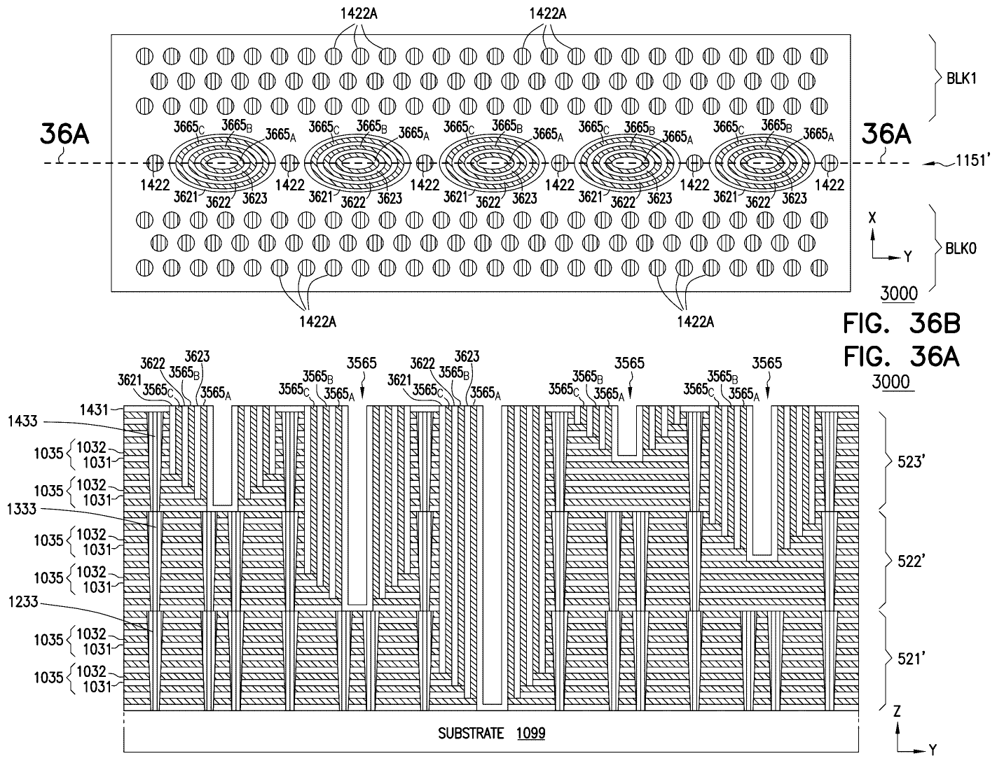

FIG. 36A and FIG. 36B show memory device 3000 after spacers 3621, 3622, and 3623, and spacers 3665_{A}, 3665_{B}, and 3665_{C} are formed. Spacers 3621, 3622, and 3623 can be called dielectric spacers (or alternatively, dielectric liners). Each of spacers 3621, 3622, and 3623 can include a dielectric material (e.g., silicon dioxide). Each of spacers 3665_{A}, 3665_{B}, and 3665_{C} can include a dielectric material (e.g., silicon nitride) that is different from the dielectric materials of spacers 3621. Spacers 3621, 3622, and 3623 and spacers 3665_{A}, 3665_{B}, and 3665_{C} can be formed one after another (e.g., in a sequential fashion). For example, spacer 3621 can be formed, then spacer 3665_{C} can be formed after spacer 3621 is formed. Then, spacer 3622 can be formed and spacer 3665_{C} can be formed after spacer 3622 is formed. Finally, spacer 3623 can be formed and spacer 3665_{A} can be formed after spacer 3623 is formed.

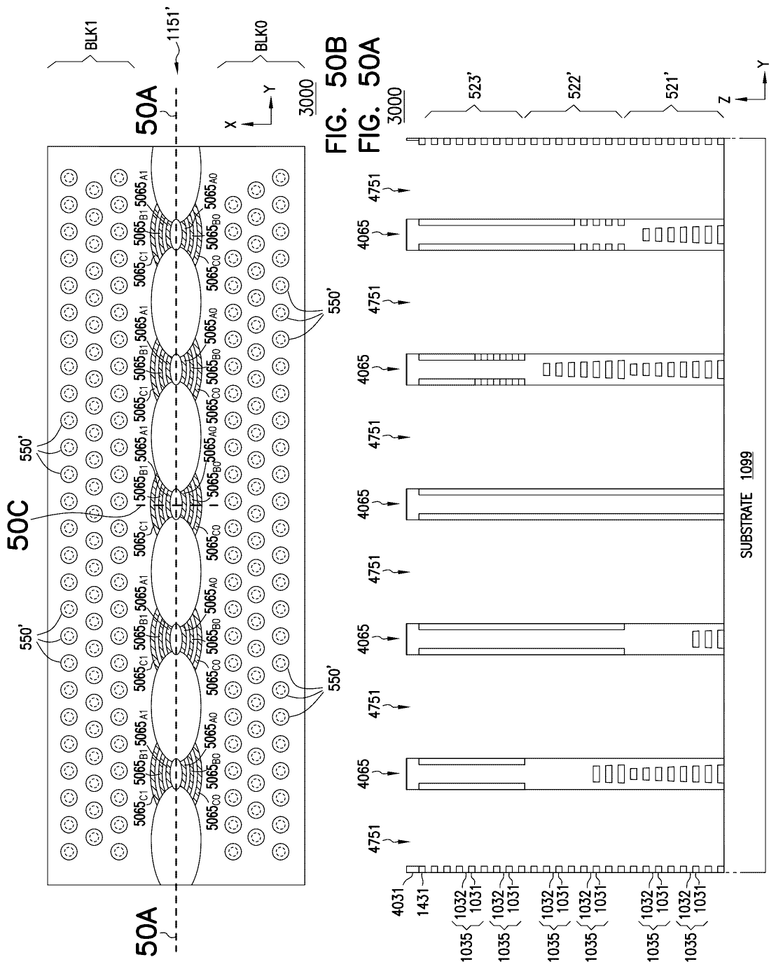

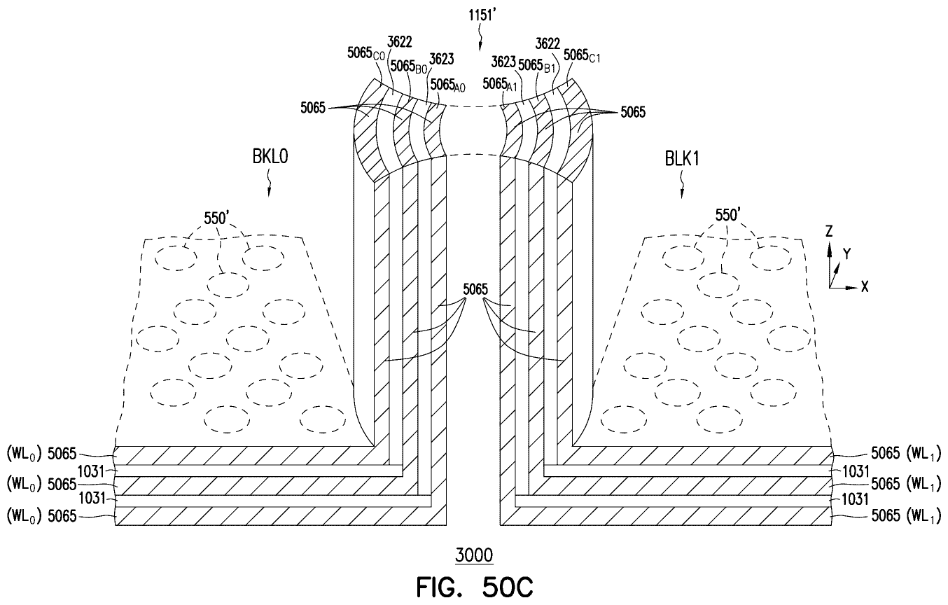

FIG. 36A and FIG. 36B show an example of three spacers 3621, 3622, and 3623 and three associated spacers 3665_{A}, 3665_{B}, and 3665_{C} (three pairs of spacers) formed in a respective opening 3565. However, the number of spacers formed in a respective opening 3565 can be different from that shown in FIG. 36A and FIG. 36B. The number of spacers formed in a respective opening 3565 can be based on the number of adjacent conductive contacts (e.g., conductive contacts 5065_{A0}, 5065_{B0}, and 5065_{C0} in FIG. 50) that are formed in the same contact opening (e.g., opening 3565).

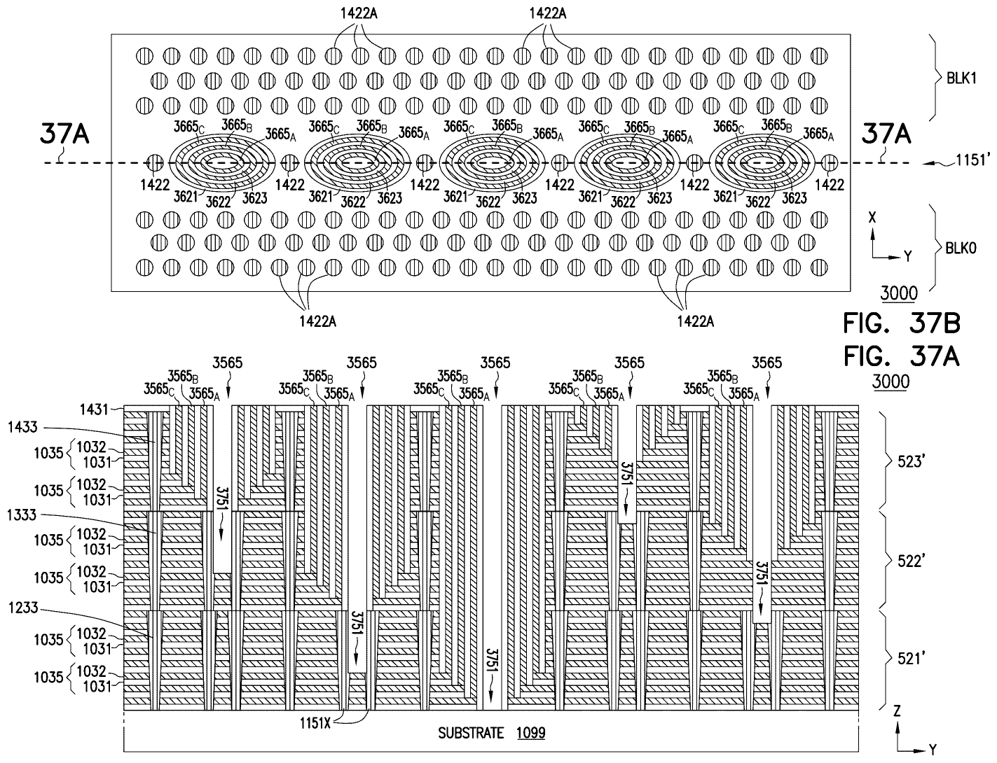

FIG. 37A and FIG. 37B show memory device 3000 after a portion of material directly under openings 3565 is removed to form cuts 3751 under respective openings 3565. Cuts 3751 are open spaces (e.g., holes). Cuts 3751 can be formed to expose the deepest openings (e.g., openings 1151X in deck 521′) that were filled with sacrificial material (e.g., material 1233 formed in FIG. 32A).

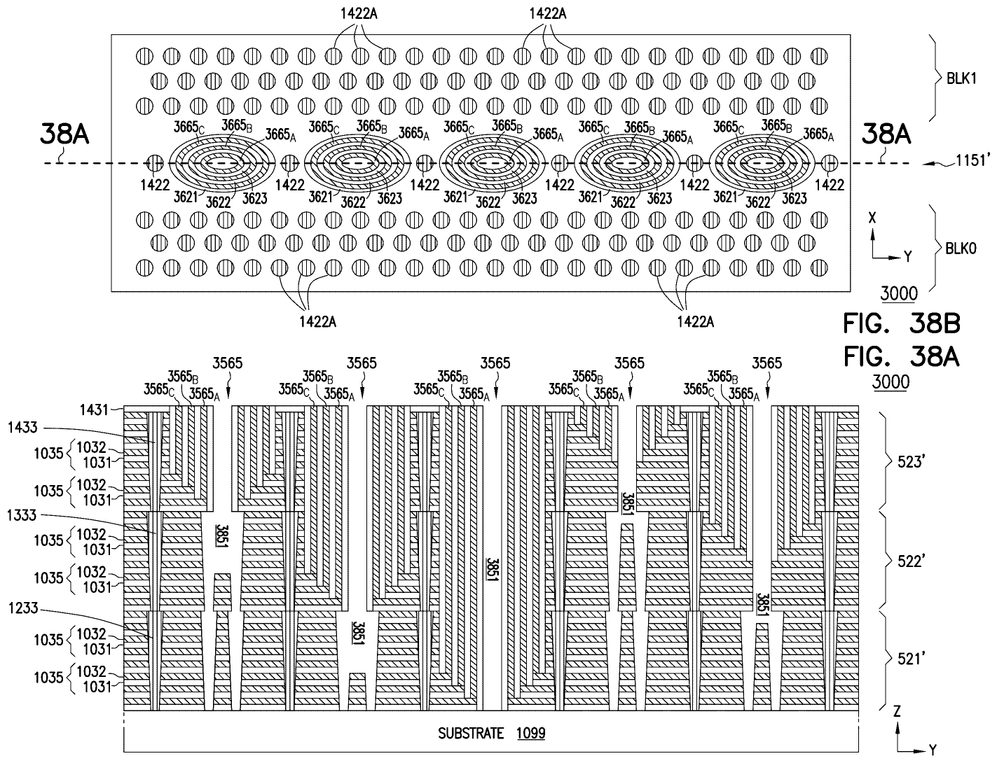

FIG. 38A and FIG. 38B show memory device 3000 after material 1233 and 1333 (sacrificial materials) at a portion of deck 521′ and a portion of deck 522′ are removed (e.g., exhumed) through cuts 3751. As shown in FIG. 38A, open spaces 3851 are formed at the locations where materials 1233 and 1333 were removed.

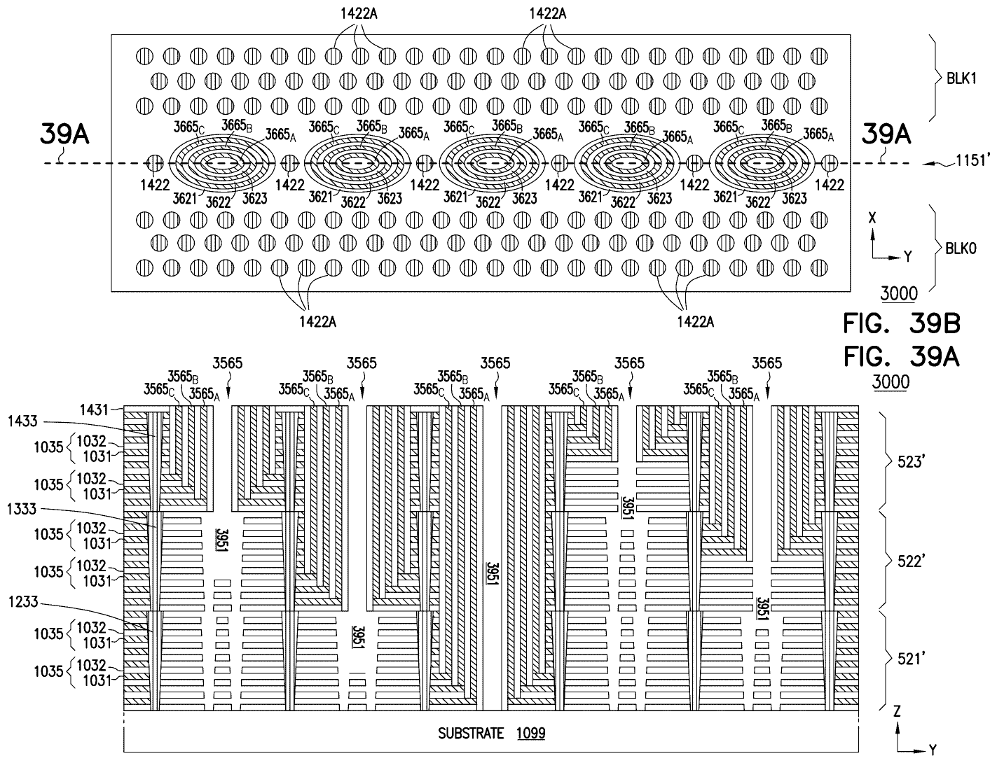

FIG. 39A and FIG. 39B show memory device 3000 after a removal of dielectric materials 1032 (e.g., silicon nitride of tiers 1035) that were exposed at open spaces 3851 in FIG. 38A. An etch process can be used to remove dielectric materials 1032. As shown in FIG. 39A, open spaces 3951 are formed under respective openings 3565. Open spaces 3951 include open spaces 3851 and the spaces that the removed dielectric materials 1032 occupied in FIG. 38A.

FIG. 40A and FIG. 40B show memory device 3000 after dielectric contact structures 4065 are formed. Forming dielectric contact structures 4065 includes forming (e.g., filling) a dielectric material (e.g., silicon dioxide) 4031 in open spaces 3951 and openings 3565 of FIG. 39A.

FIG. 40C shows a side view of memory device 3000 at line 40C of FIG. 40B after materials 1233, 1333, and 1433 (shown in FIG. 40A) are removed from the locations of pillars 1422A.

FIG. 40D shows memory device 3000 of FIG. 40C after memory cells (not labeled) and associated pillars 550′ are formed at the locations of openings 1442A (FIG. 40C). The memory cells and associated pillars 550′ of memory device 3000 of FIG. 40B and FIG. 40D are similar to memory cells 210, 211, 212, and 213, and pillars 550, respectively, of memory device 200 of FIG. 5.

The processes of forming memory cells and associated pillars 550′ associated with FIG. 40D can include forming elements that can include storage charge structures and channels (e.g., pillar channels) of the memory cells. After the memory cells and pillars 550′ are formed, they can be covered (e.g., masked) while additional processes are performed at region 1151′ and pillars 1422 as described below.

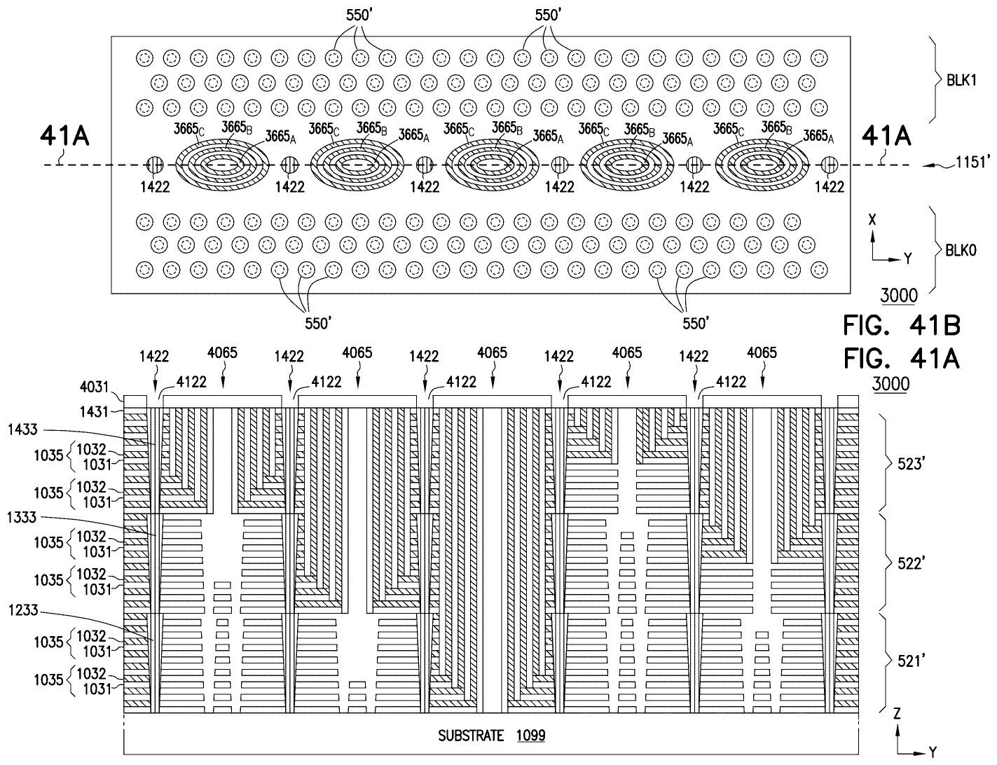

FIG. 41A and FIG. 41B show memory device 3000 after patterns (e.g., openings) 4122 are formed over pillars 1422. Patterns 4122 can expose the materials of pillars 1422. For simplicity, the top view of spacer 3621 is not shown in FIG. 41A and other subsequent figures.

FIG. 42A and FIG. 42B show memory device 3000 after openings 4251 are formed in the location of pillars 1422 (labeled in FIG. 41B). Forming openings 4251 can include removing materials 1233, 1333, and 1433 from respective pillars 1422 through pattern 4122 (labeled in FIG. 41A).

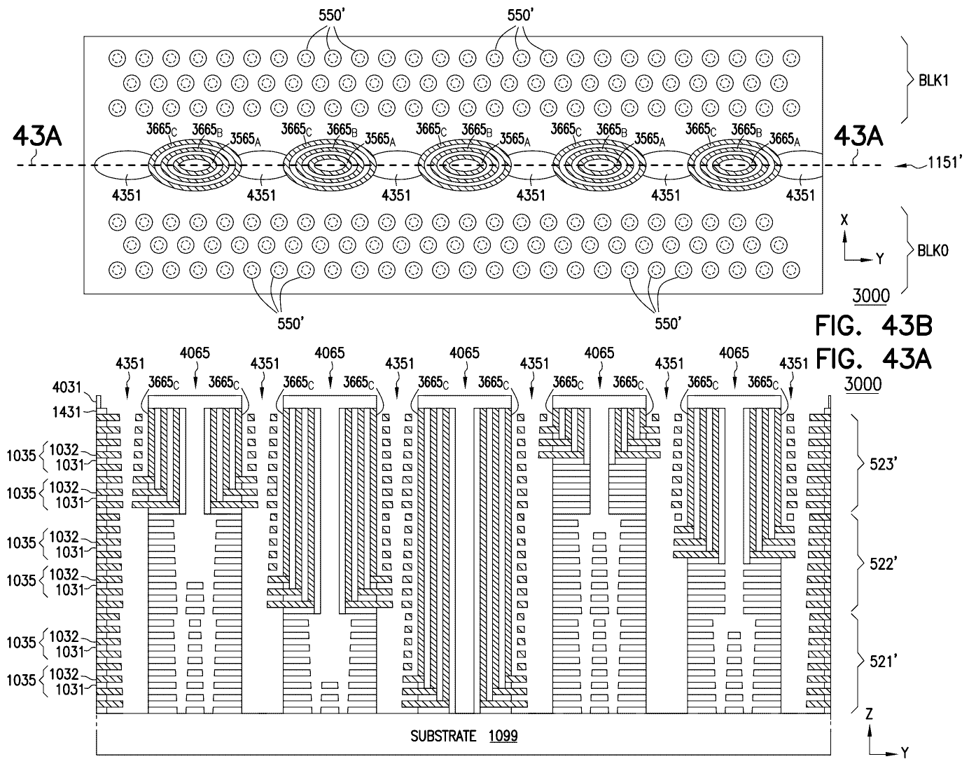

FIG. 43A and FIG. 43B show memory device 3000 after openings 4351 are formed in the location of openings 4251 (FIG. 42B). Forming openings 4351 can include removing (e.g., etching) dielectric materials (e.g., silicon dioxide) 1031 from region 1151′. As shown in FIG. 43A, openings 4351 can be formed to expose the side walls (e.g., vertical side walls, not labeled) of spacers (e.g., silicon nitride spacer) 3665_{C} at openings 4351. Some of dielectric materials 1031 (in tiers 1035) are also exposed at openings 4351.

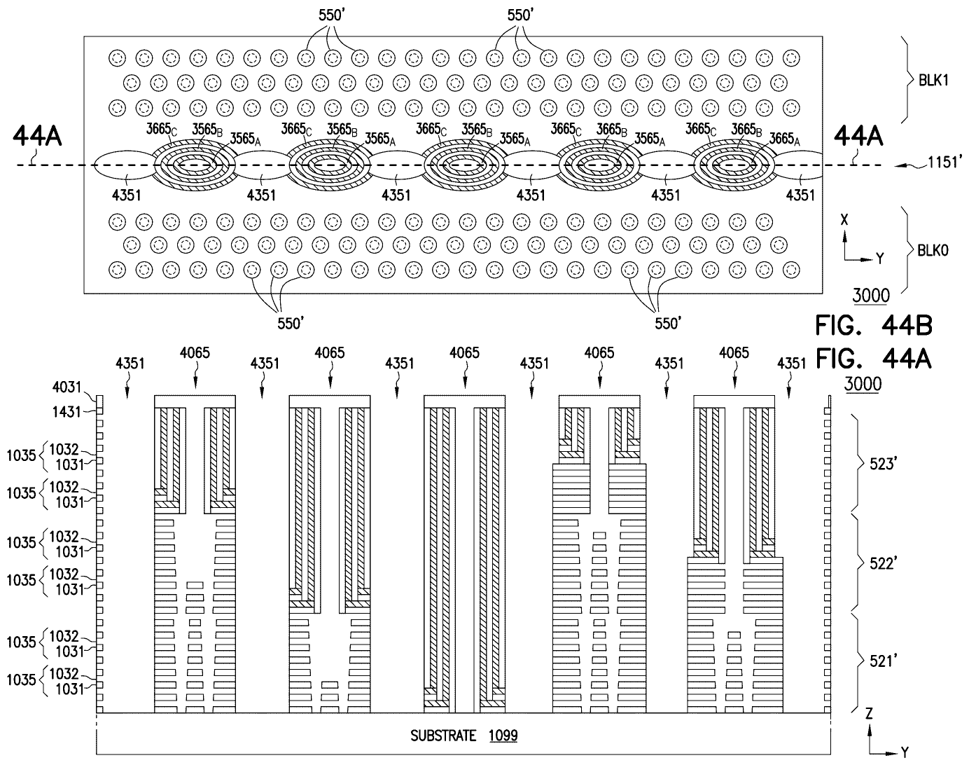

FIG. 44A and FIG. 44B show memory device 3000 after respective portions (exposed portions) of spacers 3665_{C} at openings 4351 are removed (e.g., etched). Dielectric materials 1032 (in tiers 1035) exposed at openings 4351 can also be removed (e.g., etched). Respective portions (e.g., vertical portions) of contact structures 4065 at openings 4351 can also be removed.

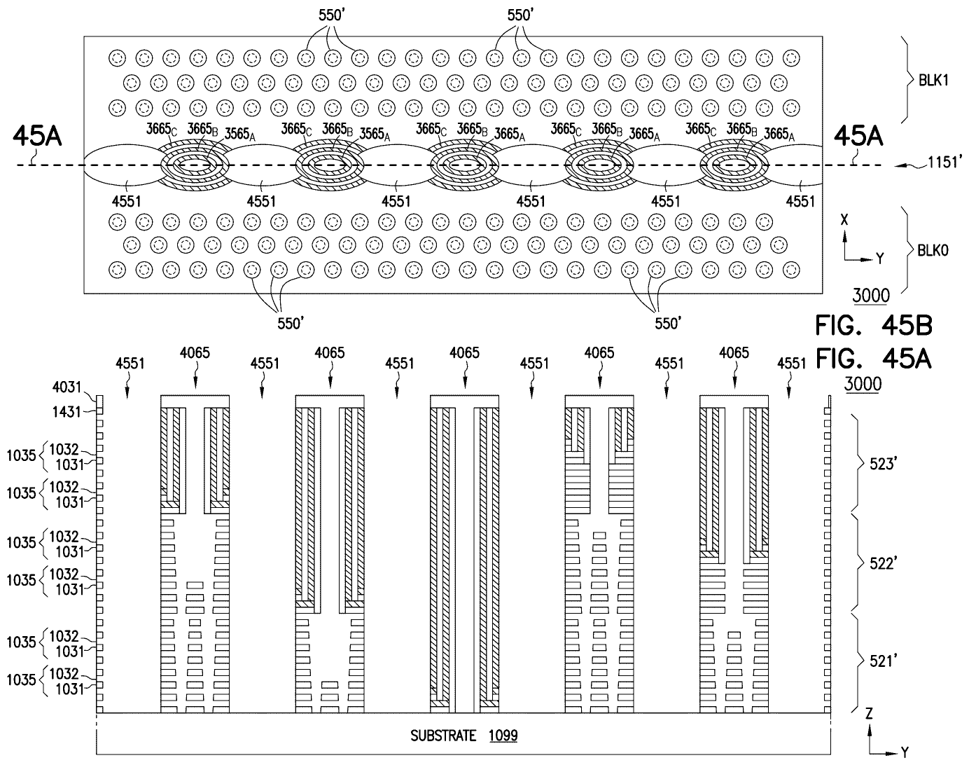

FIG. 45A and FIG. 45B show memory device 3000 after openings 4551 are formed in the location of openings 4351 (FIG. 44B). Forming openings 4551 can include removing (e.g., etching) dielectric materials (e.g., silicon dioxide) 1031 from region 1151′. As shown in FIG. 45A, openings 4551 can be formed to expose the side walls (e.g., vertical side walls, not labeled) of spacers (e.g., silicon nitride spacer) 3665_{B} at openings 4551.

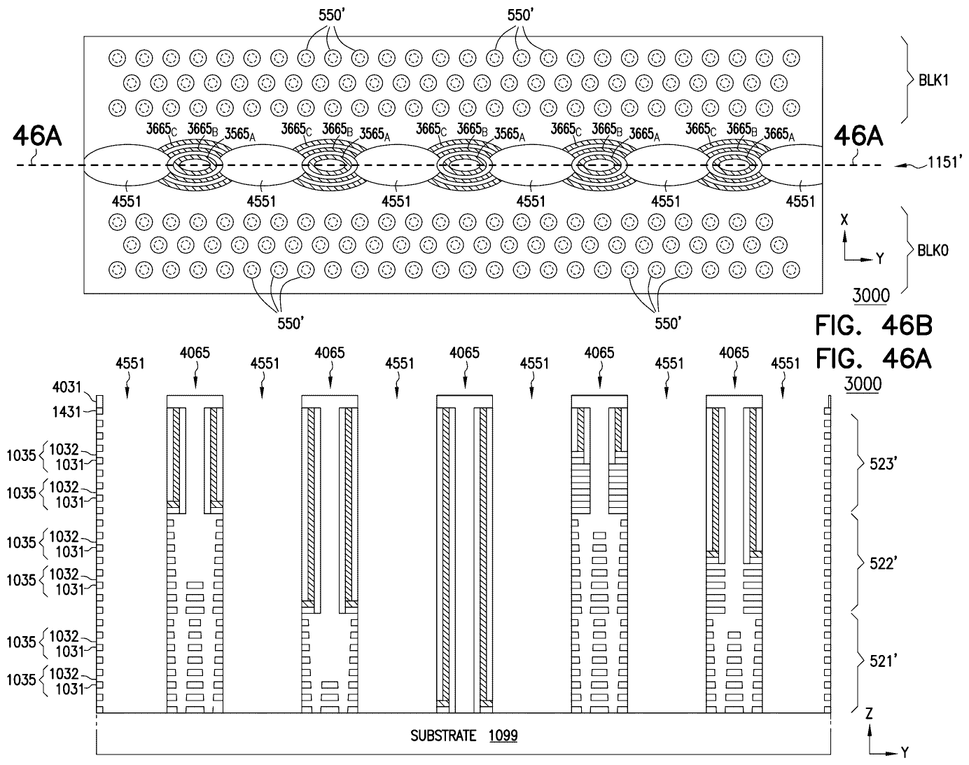

FIG. 46A and FIG. 46B show memory device 3000 after respective portions (exposed portions) of spacers 3665_{B} at openings 4551 are removed (e.g., etched). Respective portions (e.g., vertical portions) of contact structures 4065 at openings 4551 can also be removed.

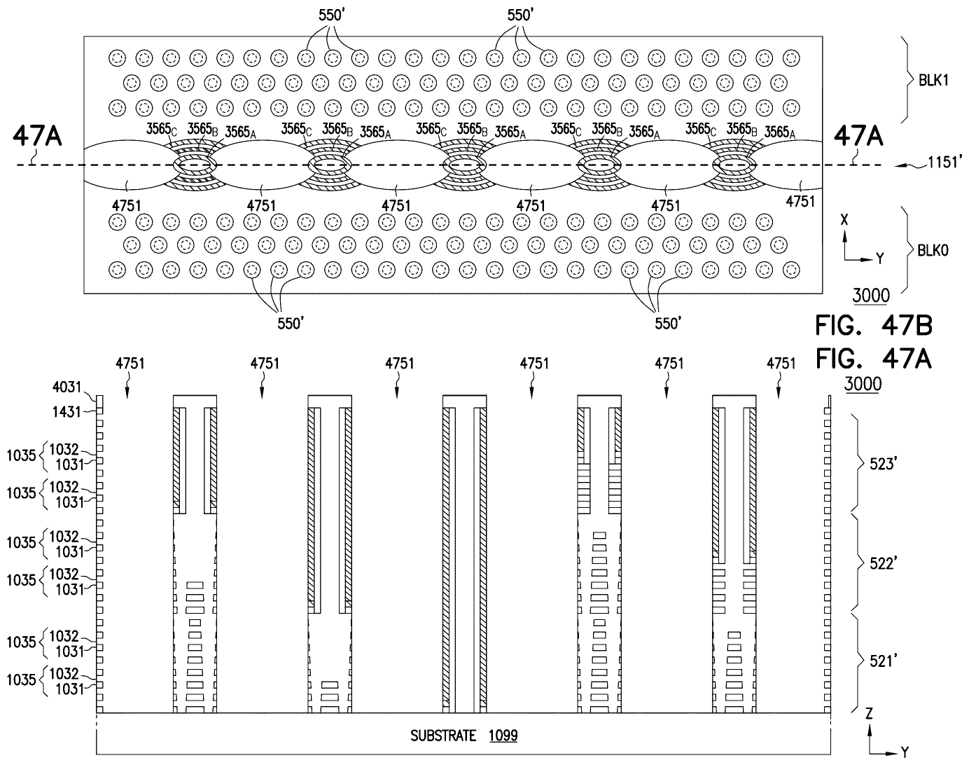

FIG. 47A and FIG. 47B show memory device 3000 after openings 4751 are formed in the location of openings 4551 (FIG. 46B). Forming openings 4751 can include removing (e.g., etching) dielectric materials (e.g., silicon dioxide) 1031 from region 1151′. As shown in FIG. 47A, openings 4751 can be formed to expose the side walls (e.g., vertical side walls, not labeled) of spacers (e.g., silicon nitride spacer) 3665_{A} at openings 4751.

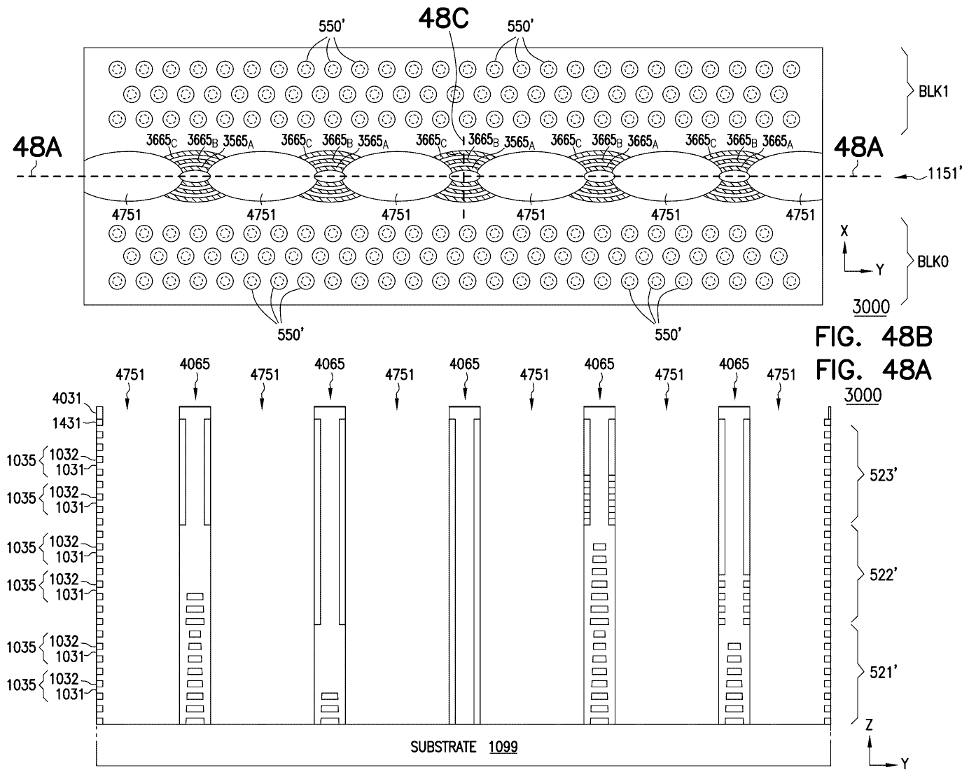

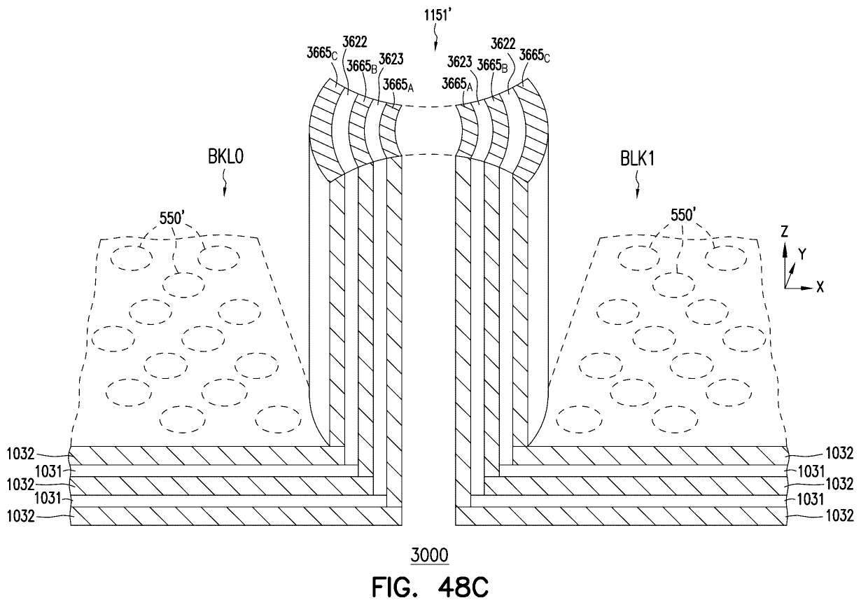

FIG. 48A and FIG. 48B show memory device 3000 after respective portions (exposed portions) of spacers 3665_{A} at openings 4551 are removed (e.g., etched). Respective portions (e.g., vertical portions) of contact structures 4065 at openings 4751 can also be removed. FIG. 48C shows a perspective view of memory device 3000 along line 48C of FIG. 48B. For simplicity, only three tiers 1035 of memory device 3000 are shown in FIG. 48C.

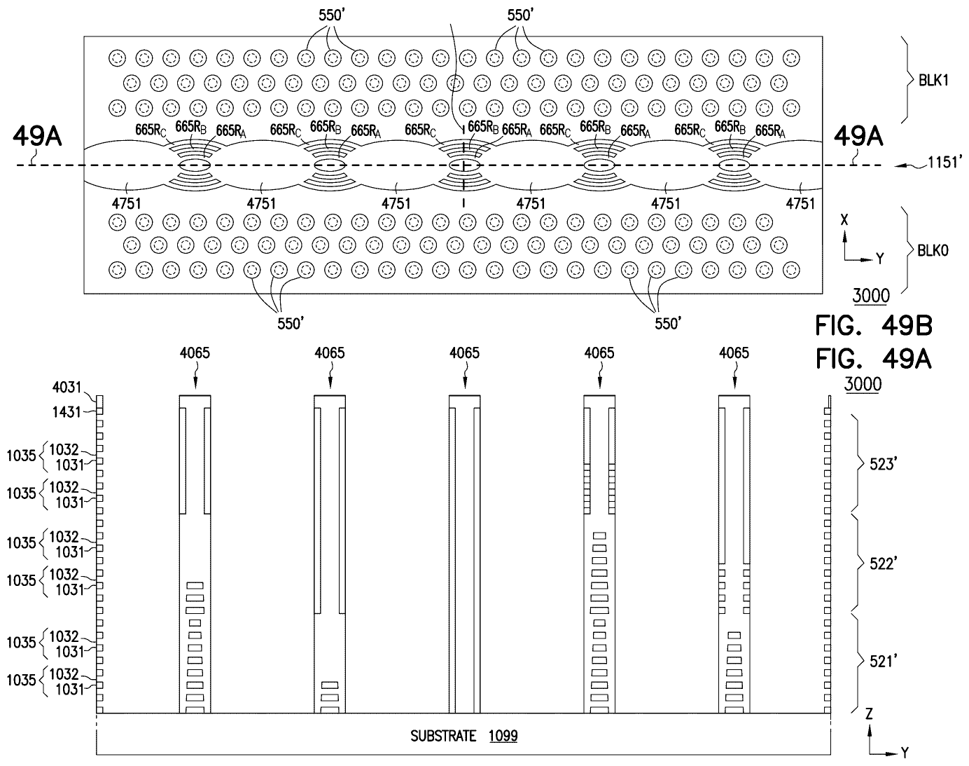

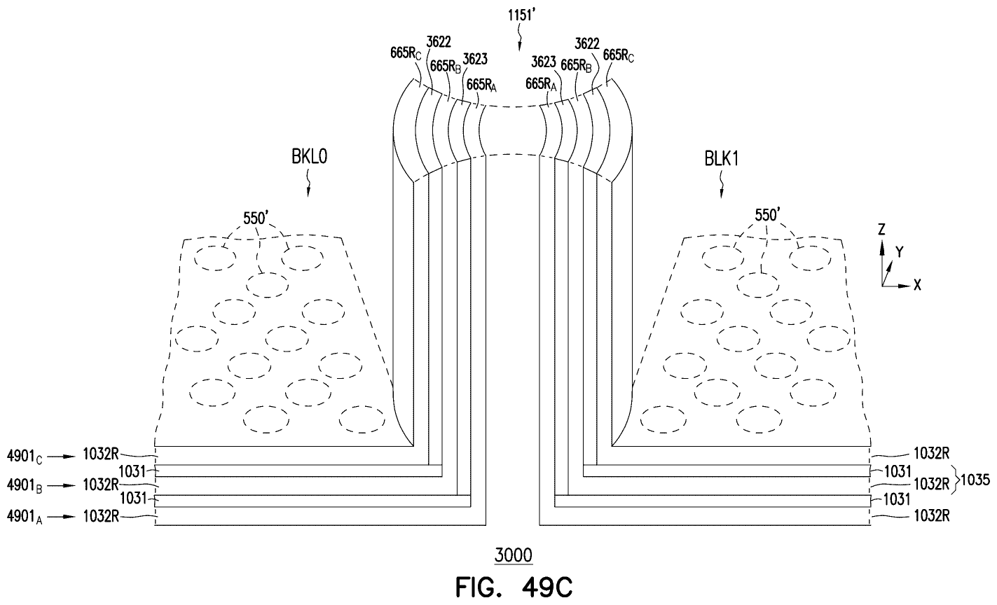

FIG. 49A, FIG. 49B, and FIG. 49C show memory device 3000 after spacers 3665_{A}, 3665_{B}, and 3665_{C} (labeled in FIG. 48B and FIG. 48C) are removed (e.g., exhumed). FIG. 49C shows a perspective view of memory device 3000 along line 49C of FIG. 49B. In FIG. 49B and FIG. 49C, openings 665R_{A}, 665R_{B}, and 665R_{C} (which have curve shapes) are the locations that spacers 3665_{A}, 3665_{B}, and 3665_{C} in FIG. 48B occupied before spacers 3665_{A}, 3665_{B}, and 3665_{C} were removed.

As shown in FIG. 49C, openings 665R_{A}, 665R_{B}, and 665R_{C} are separated from each other by remaining portions of spacers 3622 and 3623. Spacers 3621 adjacent openings 665R_{C} are not shown in FIG. 49C.

FIG. 49C also shows memory device 3000 after dielectric materials (e.g., silicon nitride) 1032 at the regions (memory array region) of blocks BLK0 and BLK1 are removed (e.g., exhumed) from locations 1032R. Locations 1032R in FIG. 49C are voids (empty spaces) that were occupied by dielectric materials 1032 (FIG. 48C) before dielectric materials 1032 were removed.

As shown in FIG. 49C, openings 665R_{A}, 665R_{B}, and 665R_{C} can joint (form a continuous access path) with voids (empty spaces) at respective locations 1032R in tiers 1035 of respective blocks BLK0 and BLK1. Tiers 1035 of respective blocks BLK0 and BLK1 that are coupled to respective openings 665R_{A}, 665R_{B}, and 665R_{C} can be located in the same level in the Z-direction. For example, tiers 1035 coupled to openings 665R_{A} of respective of blocks BLK0 and BLK1 are located on the same level (e.g., level 4901_{A}). Tiers 1035 coupled to openings 665R_{B} of respective of blocks BLK0 and BLK1 are located on the same level (e.g., level 4901_{B}). Tiers 1035 coupled to openings 665R_{C} of respective of blocks BLK0 and BLK1 are located on the same level (e.g., level 4901_{C}).

In subsequent processes (FIG. 50C), a conductive material (e.g., conductive material 5065 in FIG. 50C) can be concurrently formed in openings 665R_{A}, 665R_{B}, and 665R_{C} and in locations 1032R. As described below, the conductive material (conductive material 5065 in FIG. 50C) in locations 1032R forms control gates of blocks BLK0 and BLK1. The conductive material (the same conductive material 5065 in FIG. 50C) in openings 665R_{A}, 665R_{B}, and 665R_{C} (FIG. 50C) forms conductive contacts of block BLK0 and BLK1 associated with (contacting) respective control gates (which are also formed from conductive material 5065 in FIG. 50C). Thus, in memory device 3000, forming the conductive contacts and forming the control gates can occur concurrently (e.g., occur in situ).

FIG. 50A, FIG. 50B, and FIG. 50C show memory device 3000 after conductive material (or conductive materials) 5065 are formed in locations 1032R (labeled in FIG. 49C) and in openings 665R_{A}, 665R_{B}, and 665R_{C} (labeled in FIG. 49C). Conductive material 5065 can be similar to or the same as conductive material 522 of FIG. 5A. For example, conductive material 5065 can include a single material (e.g., metal) or a combination of (e.g., different layers of) conductive materials (e.g., metal and other conductive material). For example, conductive material 5065 can include tungsten or a combination of tungsten and other conductive materials (e.g., titanium nitride or other conductive materials).

FIG. 50C shows a perspective view of memory device 3000 along line 50C of FIG. 50B. As shown in FIG. 50A and FIG. 50C, respective portions of conductive material 5065 form conductive contacts 5065_{A0}, 5065_{B0}, and 5065_{C0} in block BLK0 and conductive contacts 5065_{A1}, 5065_{B1}, and 5065_{C1} in block BLK1. As shown in FIG. 50C, respective portions of conductive material 5065 forms the control gates (associated with signals WL₀) associated with conductive contacts 5065_{A0}, 5065_{B0}, and 5065_{C0} in block BLK0. As shown in FIG. 50C, conductive material 5065 forms the control gates (associated with signals WL₁) associated with conductive contacts 5065_{A1}, 5065_{B1}, 5065_{C1} in block BLK1. For simplicity, only three control gates in each of blocks BLK0 and BLK1 are shown in FIG. 50C.

As shown in FIG. 29, conductive contacts 5065_{A0}, 5065_{B0}, and 5065_{C0} can include respective side walls (e.g., vertical curved side walls, not labeled) and are separated from each other by respective spacers 3622 and 3623 in block BLK0. Conductive contacts 5165_{A1}, 5165_{B1}, and 5165_{C1} can include respective side walls (e.g., vertical curved side walls, not labeled) and are separated from each other by respective spacers 3622 and 3623 in block BLK1.

Conductive contacts 5065_{A0}, 5065_{B0}, and 5065_{C0} can correspond to (e.g., can represent) conductive contacts 665_{A0}, 665_{B0}, and 665_{C0}, respectively, of FIG. 28 and FIG. 29. Conductive contacts 5165_{A1}, 5165_{B1}, and 5165_{C1} can correspond to (e.g., can represent) conductive contacts 665_{A1}, 665_{B1}, and 665_{C1}, respectively, of FIG. 28 and FIG. 29. Spacers 3622 and 3623 correspond to (e.g., can represent) spacers 2622 and 2623, respectively, of FIG. 28 and FIG. 29.

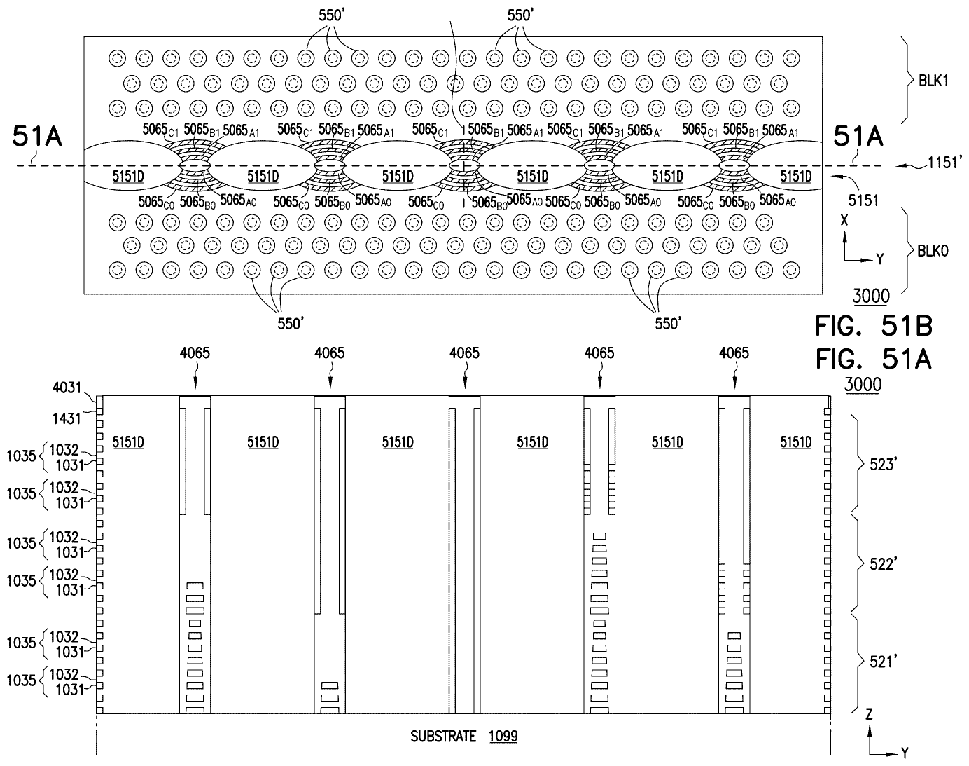

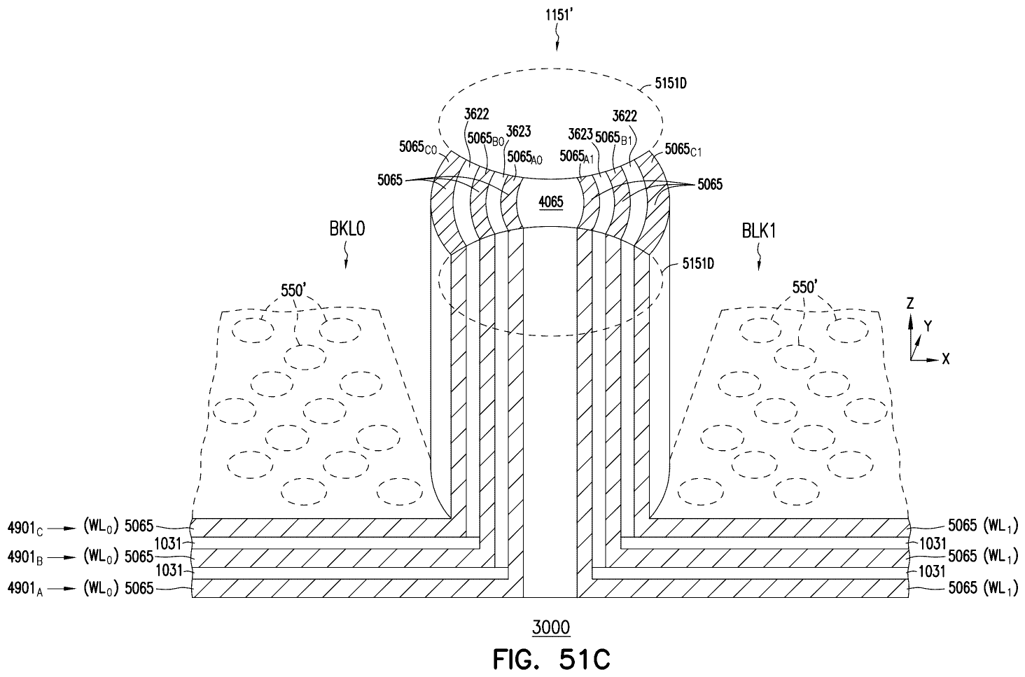

FIG. 51A, FIG. 51B, and FIG. 51C show memory device 3000 after a dielectric structure 5151 is formed in region 1151′. Forming dielectric structure 5151 can include forming (e.g., filling) a dielectric material (or materials) 5151D in region 1151′. FIG. 51C shows a perspective view of memory device 3000 along line 51C of FIG. 51B. As shown in FIG. 51C, dielectric structure 5151 separates (physically separates) conductive materials 5056 (which form respective control gates) in levels 4901_{A}, 4901_{B}, and 4901_{C} in block BLK0 from conductive materials 5056 (which form respective control gates) in levels 4901_{A}, 4901_{B}, and 4901_{C} in block BLK1.

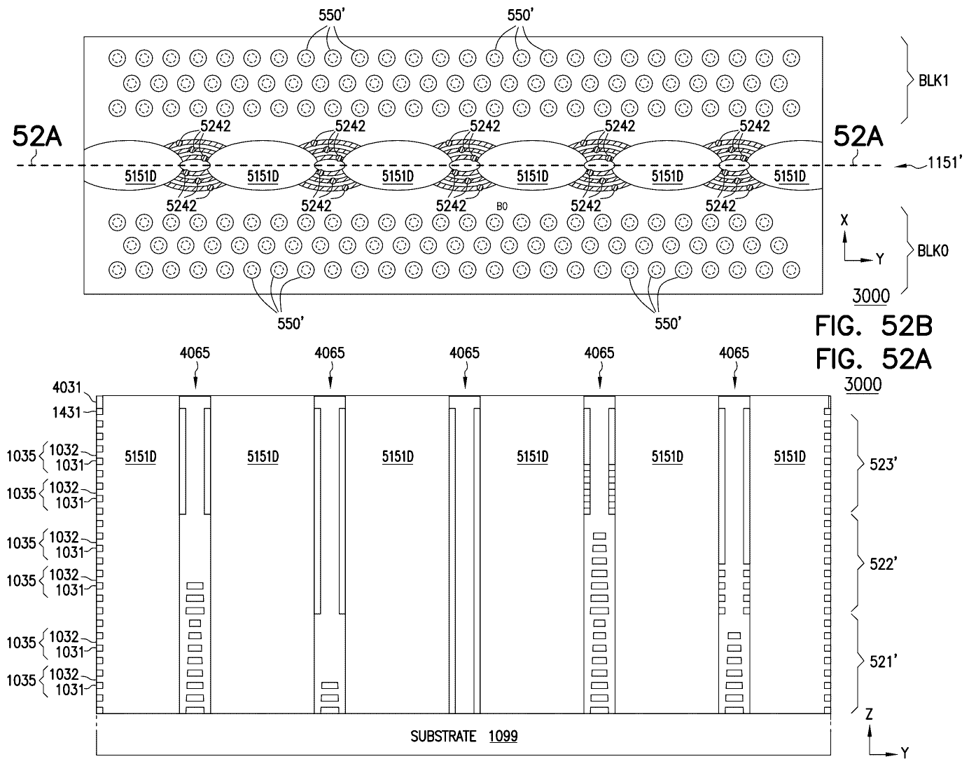

FIG. 52A and FIG. 52B show memory device 3000 after conductive connections 5242 are formed over (e.g., formed on) respective conductive contacts 5065_{A0}, 5065_{B0}, and 5065_{C0} in block BLK0 and respective conductive contacts 5065_{A1}, 5065_{B1}, and 5065_{C1} in block BLK1. In subsequent processes (not described), conductive lines (e.g., similar to conductive lines 656 of FIG. 29) of memory device 3000 can be formed to connect conductive connections 5242 to other components (e.g., word line drivers) of memory device 3000.

The processes of forming memory device 3000 described above with reference to FIG. 30A through FIG. 52B can include other processes to form a complete memory device (e.g., memory device 3000). Such processes are omitted from the above description so as not to obscure the subject matter described herein. Improvements and benefits of memory device 3000 are similar to or the same as improvements and benefits of memory devices 200 and 2600 described above.

The illustrations of apparatuses (e.g., memory devices 100, 200, 800, 1000, and 3000) and methods (e.g., method of forming memory devices 1000 and 3000) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 800, 1000, and 3000) or a system (e.g., a computer, a cellular phone, or other electronic systems) that includes a device such as any of memory devices 100, 200, 800, 1000, and 3000.

Any of the components described above with reference to FIG. 1 through FIG. 52B can be implemented in a number of ways, including simulation via software. Thus, apparatuses, e.g., memory devices 100, 200, 800, 1000, and 3000 or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 800, 1000, and 3000 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 52B include apparatuses and methods of forming the apparatuses. One of the apparatuses includes: levels of dielectric materials interleaved with the levels of conductive materials; a memory cell string including a pillar extending through the levels of conductive materials and the levels of dielectric materials, the levels of conductive materials including a first conductive level forming a first control gate associated with the memory cell string, and a second conductive level forming a second control gate associated with the memory cell string; a first conductive contact contacting the first conductive level; and a second conductive contact separated from the first conductive contact and contacting the second conductive level, at least a portion of the second conductive contact surrounding a portion of the first conductive contact. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
levels of conductive materials;
levels of dielectric materials interleaved with the levels of conductive materials;
a memory cell string including a pillar extending through levels of conductive materials and the levels of dielectric materials, the levels of conductive materials including a first conductive level forming a first control gate associated with the memory cell string, and a second conductive level forming a second control gate associated with the memory cell string;
a first conductive contact contacting the first conductive level; and
a second conductive contact separated from the first conductive contact and contacting the second conductive level, at least a portion of the second conductive contact surrounding a portion of the first conductive contact.

2. The apparatus of claim 1, wherein a cross-section of the second conductive contact has a ring shape.

3. The apparatus of claim 1, wherein the first conductive level is adjacent the second conductive level.

4. The apparatus of claim 1, further comprising a dielectric material between the first conductive contact and the second conductive contact and surrounding the first conductive contact.

5. The apparatus of claim 4, further comprising an additional dielectric material between the second conductive contact and a portion of the levels of dielectric materials and a portion of the levels of conductive materials, wherein additional dielectric material surrounds the second conductive contact.

6. The apparatus of claim 1, further comprising a third conductive contact separated from the first conductive contact and the second conductive contact and contacting a third conductive level of the levels of conductive materials, wherein at least a portion of the third conductive contact surrounds a portion of the second conductive contact.

7. The apparatus of claim 1, wherein:
the first conductive level includes a first edge;
the second conductive level includes a second edge;
the first conductive contact is between the pillar and the first edge, and the first conductive contact is between the pillar and the second edge; and
the second conductive contact is between the pillar and the first edge, and the second conductive contact is between the pillar and the second edge.

8. The apparatus of claim 7, wherein the first conductive contact and the second conductive contact are adjacent each other, and the first conductive level and the second conductive level are adjacent each other.

9. An apparatus comprising:
a first region including first levels of conductive materials interleaved with first levels of dielectric materials, and first memory cells including pillars extending through at least a portion of the first levels of conductive materials and first levels of dielectric materials;
a second region including second levels of conductive materials interleaved with second levels of dielectric materials, and second memory cells including pillars extending through at least a portion of the first levels of conductive materials and first levels of dielectric materials;
a third region including a dielectric structure separating the first levels of conductive materials from the second levels of conductive materials;
a first conductive contact extending through at least a portion of the third region and contacting a level of the first levels of conductive materials; and
a second conductive contact adjacent the first conductive contact, the second conductive contact extending through at least a portion of the third region and contacting an additional level of the first levels of conductive materials.

10. The apparatus of claim 9, further comprising a dielectric spacer between the first conductive contact and the second conductive contact, wherein:
the dielectric structure includes a dielectric portion, the dielectric portion including a side wall;
the first conductive contact is adjacent the side wall of the dielectric portion and a first side wall of the dielectric spacer; and
the second conductive contact is adjacent a second side wall of the dielectric spacer.

11. The apparatus of claim 10, further comprising a third conductive contact adjacent the second conductive contact, the third conductive contact extending through at least a portion of the third region and contacting one of the first levels of conductive materials.

12. The apparatus of claim 11, further comprising an additional dielectric spacer between the second the conductive contact and the third conductive contact, wherein:
the second conductive contact is adjacent a first side wall of the additional dielectric spacer; and
the third conductive contact is adjacent a second side wall of the additional dielectric spacer.

13. The apparatus of claim 9, further comprising:
a first additional conductive contact extending through at least a portion of the third region and contacting a level of the second levels of conductive materials; and
a second additional conductive contact adjacent the first additional conductive contact, the second additional conductive contact extending through at least a portion of the third region and contacting an additional level of the second levels of conductive materials.

14. The apparatus of claim 9, wherein the conductive material of the first levels of conductive materials and the conductive material of the second levels of conductive materials are located on a same level of the apparatus.

15. The apparatus of claim 9, wherein the first levels of conductive materials form first control gates associated with the first memory cells, and the second levels of conductive materials form second control gates associated with the second memory cells.

16. The apparatus of claim 9, wherein the apparatus comprises a memory device, the memory device including a first memory cell block and a second memory cell block, wherein the first memory cells are included in the first memory cell block, and the second memory cells are included in the second memory cell block.

17. A method comprising:
forming levels of first materials interleaved with levels of second materials;
forming memory cells including forming a pillar associated with the memory cells through the levels of first materials and the levels of second materials;
forming an opening through the levels of first materials and the levels of second materials;
forming a first dielectric material in the opening;
forming a first conductive contact in the opening and contacting a first level of the levels of first materials;
forming a second dielectric material in the opening, such that the first conductive contact is between the first dielectric material and the second dielectric material; and
forming a second conductive contact in the opening, such that the second dielectric material is between the first conductive contact and the second conductive contact, wherein the second conductive contact contacts a second level of the levels of first materials.

18. The method of claim 17, wherein forming the levels of first materials includes:
forming a conductive material at locations of the levels of first materials and locations of the first conductive contact and the second conductive contact, wherein the levels of first materials, first conductive contact, and the second conductive contact include respective portions of the conductive material.

19. The method of claim 18, wherein the conductive material is formed after the first dielectric material is formed and after the second dielectric material is formed.

20. The method of claim 17, further comprising:
forming a dielectric structure in a region between a first portion of the memory cells and a second portion of the memory cells to separate a first portion of the levels of first materials from a second portion of the levels of first materials, wherein:
the first conductive contact and the second conductive contact are formed in the region between the first portion of the memory cells and the second portion of the memory cells.
